(19) United States
(12) Patent Application Publication
(10) Pub. No.: US 2026/0026083 A1
(43) Pub. Date: Jan. 22, 2026

(54) CAPACITOR WITH AN INTRA-ELECTRODE OXYGEN CONTAINING INTERFACIAL LAYER AND METHOD OF MAKING THE SAME

(71) Applicant: SANDISK TECHNOLOGIES LLC, ADDISON, TX (US)

(72) Inventors: Kyoko UMEDA, Yokkaichi (JP); Daisuke MIYAKE, Yokkaichi (JP); Takahiro MIDO, Yokkaichi (JP)

(21) Appl. No.: 18/779,616

(22) Filed: Jul. 22, 2024

(51) Int. Cl. H01L 27/06; H01L 21/02; H01L 29/04; H01L 29/06; H01L 29/49; H01L 29/66; H01L 29/78; H01L 29/94

(52) U.S. Cl. CPC H10D 84/811; H01L 21/02667; H10D 1/047; H10D 1/66; H10D 30/60; H10D 62/115; H10D 62/40; H10D 64/666; H10D 64/667

(57) ABSTRACT

A capacitor includes a bottom electrode including a substrate doped semiconductor portion located within a substrate, a bottom node dielectric located on a top surface of the bottom electrode, a middle electrode including a middle doped semiconductor portion located on the bottom node dielectric, a top node dielectric located on a top surface of the middle electrode, and a top electrode including, from bottom to top, an electrically-doped semiconductor portion, an oxygen containing interfacial layer, an electrically-undoped semiconductor portion, and at least one electrode metallic layer.

### FIELD

The present disclosure relates generally to the field of semiconductor devices, and particularly to a capacitor including an intra-electrode oxygen containing interfacial layer and methods for manufacturing the same.

### BACKGROUND

A capacitor may include a capacitor dielectric layer, such as a silicon oxide layer, between opposing electrically conductive electrodes.

### SUMMARY

According to an aspect of the present disclosure, a capacitor includes a substrate, a bottom electrode including a substrate doped semiconductor portion located within the substrate, a bottom node dielectric located on a top surface of the bottom electrode, a middle electrode including a middle doped semiconductor portion located on the bottom node dielectric, a top node dielectric located on a top surface of the middle electrode, and a top electrode including, from bottom to top, an electrically-doped semiconductor portion, an oxygen containing interfacial layer, an electrically-undoped semiconductor portion, and at least one electrode metallic layer.

According to another aspect of the present disclosure, a method of forming a semiconductor structure is provided, which comprises: forming a gate dielectric material layer, a gate semiconductor material layer, and a capacitor material layer stack over a substrate, wherein the capacitor material layer stack comprises, from bottom to top, a top node dielectric material layer, a first electrically-doped semiconductor layer, a first interfacial layer, and an electrically-undoped semiconductor layer; removing a first portion of the capacitor material layer stack from a transistor region while retaining at least a part of a second portion of the capacitor material layer stack in a capacitor region; forming at least one electrode metallic material layer over the second portion of the capacitor material layer stack in the capacitor region and over the gate semiconductor material layer in the transistor region; and patterning the at least one electrode metallic material layer, the second portion of the capacitor material layer stack, and the gate semiconductor material layer to form a capacitor in the capacitor region and to form a gate electrode in the transistor region.

### BRIEF DESCRIPTION OF THE DRAWINGS

FIG. 1 is a vertical cross-sectional view of an exemplary structure after formation of a substrate doped semiconductor portion according to an embodiment of the present disclosure.

FIG. 2 is a vertical cross-sectional view of the exemplary structure after formation of a gate dielectric material layer and a gate semiconductor material layer according to an embodiment of the present disclosure.

FIG. 3 is a vertical cross-sectional view of the exemplary structure after formation of shallow trench isolation structures according to an embodiment of the present disclosure.

FIG. 4 is a vertical cross-sectional view of the exemplary structure after formation of a top node dielectric material layer and an electrically-doped semiconductor layer according to an embodiment of the present disclosure.

FIG. 5 is a vertical cross-sectional view of the exemplary structure after formation of an interfacial layer according to an embodiment of the present disclosure.

FIG. 6 is a vertical cross-sectional view of the exemplary structure after formation of an electrically-undoped semiconductor layer according to an embodiment of the present disclosure.

FIG. 7 is a vertical cross-sectional view of the exemplary structure after patterning a stack of the electrically-undoped semiconductor layer, the interfacial layer, the first electrically-doped semiconductor layer, and the top node dielectric material layer according to an embodiment of the present disclosure.

FIG. 8 is a vertical cross-sectional view of the exemplary structure after formation of a capping layer stack including electrode metallic layers according to an embodiment of the present disclosure.

FIG. 9 is a vertical cross-sectional view of the exemplary structure after patterning the capping layer stack and the gate semiconductor material layer according to an embodiment of the present disclosure.

FIG. 10 is a vertical cross-sectional view of the exemplary structure after formation of a source extension region and a drain extension region according to an embodiment of the present disclosure.

FIG. 11 is a vertical cross-sectional view of the exemplary structure after formation of a middle electrode contact structure according to an embodiment of the present disclosure.

FIG. 12 is a vertical cross-sectional view of the exemplary structure after formation of a dielectric gate spacer, additional dielectric spacers, a deep source region, and a deep drain region according to an embodiment of the present disclosure.

FIG. 13 is a vertical cross-sectional view of the exemplary structure after formation of a contact-level dielectric layer and contact via cavities according to an embodiment of the present disclosure.

FIG. 14 is a vertical cross-sectional view of the exemplary structure after formation of metal-semiconductor alloy regions according to an embodiment of the present disclosure.

FIG. 15 is a vertical cross-sectional view of the exemplary structure after formation of various contact via structures according to an embodiment of the present disclosure.

FIG. 16 is a vertical cross-sectional view of an alternative configuration of the exemplary structure after formation of a top node dielectric material layer, a vertically alternating sequence of electrically-doped semiconductor layers and interfacial layers, and an electrically-undoped semiconductor layer according to an embodiment of the present disclosure.

FIG. 17 is a vertical cross-sectional view of the alternative configuration of the exemplary structure after formation of a capping layer stack including electrode metallic layers according to an embodiment of the present disclosure.

FIG. 18 is a vertical cross-sectional view of the alternative configuration of the exemplary structure after formation of a dielectric gate spacer, additional dielectric spacers, a deep source region, and a deep drain region according to an embodiment of the present disclosure.

FIG. 19 is a vertical cross-sectional view of the alternative configuration of the exemplary structure after formation of various contact via structures according to an embodiment of the present disclosure.

FIGS. 20A and 20B are magnified vertical cross-sectional views of a region of a semiconductor top electrode after an anneal process in various configurations of the exemplary structure according to embodiments of the present disclosure.

FIG. 21 is a Weibull plot for the cumulative probability of time-dependent dielectric breakdown (TDDB) failure for a comparative exemplary capacitor and for a capacitor according to an embodiment of the present disclosure.

### DETAILED DESCRIPTION

Device reliability of an integrated capacitor in a semiconductor circuit is limited by time-dependent dielectric breakdown (TDDB) of a capacitor dielectric. Embodiments of the present disclosure are directed to a capacitor containing an oxygen containing interfacial layer within a polycrystalline semiconductor capacitor electrode and methods for manufacturing the same. The interfacial layer causes disruption in the pattern of columnar grain growths during crystallization of amorphous semiconductor material to polycrystalline semiconductor material of the capacitor electrode, and reduces metal diffusion along the grains of crystallized semiconductor material from an adjacent metal layer, thereby improving the time-dependent dielectric breakdown resistance of the capacitor.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition. As used herein, a first element located “on” a second element can be located on the exterior side of a surface of the second element or on the interior side of the second element. As used herein, a first element is located “directly on” a second element if there exist a physical contact between a surface of the first element and a surface of the second element.

As used herein, a “layer” refers to a material portion including a region having a thickness. A layer may extend over the entirety of an underlying or overlying structure, or may have an extent less than the extent of an underlying or overlying structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material”, “insulating material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material upon activation of electrical dopants therein, i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

As used herein, a “field effect transistor” refers to any semiconductor device having a semiconductor channel through which electrical current flows with a current density modulated by an external electrical field. As used herein, a “channel region” refers to a semiconductor region in which flow of charge carriers (e.g., electrons or holes) is affected by an applied electrical field. A “gate electrode” refers to an electrically conductive electrode applies an electric field that controls charge carrier flow in the channel region by. A “source region” refers to a doped semiconductor region that supplies charge carriers (e.g., electrons or holes) that flow through the channel region. A “drain region” refers to a doped semiconductor region that receives the charge carriers supplied by the source region and that flow through the channel region. A “source/drain region” may be a source region or a drain region. An “active region” collectively refers to a source region, a drain region, and a channel region of a field effect transistor. A “source extension region” refers to a doped semiconductor region that is a portion of a source region and having a lesser dopant concentration than the rest of the source region. A “drain extension region” refers to a doped semiconductor region that is a portion of a drain region and having a lesser dopant concentration than the rest of the drain region. An “active region extension” refers to a source extension region or a drain extension region.

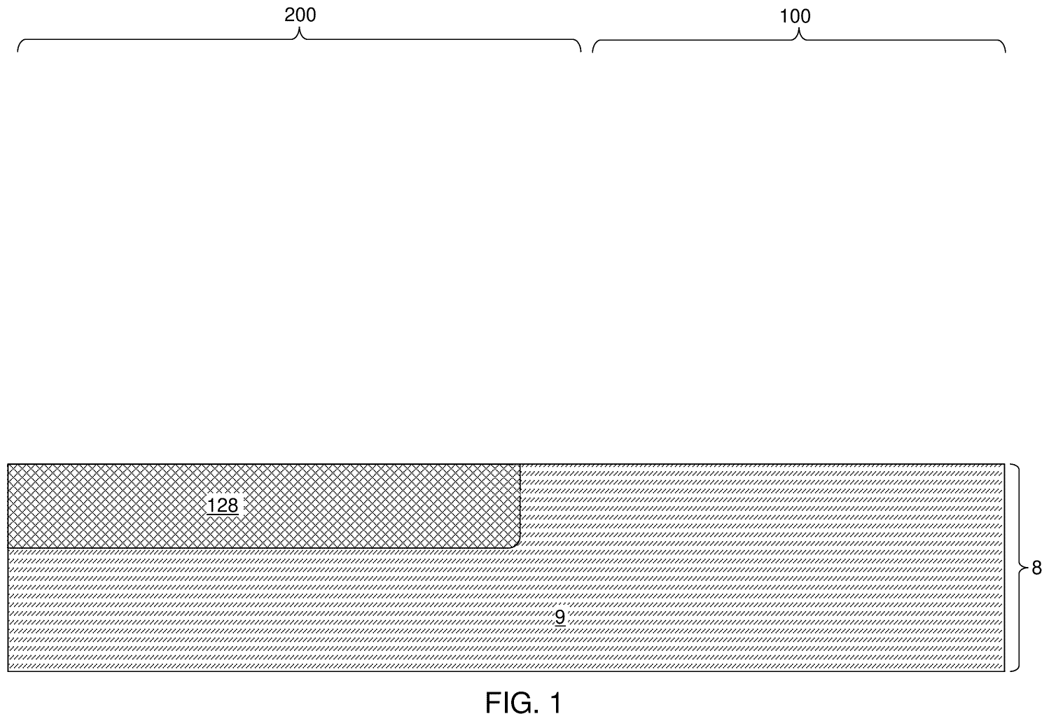

Referring to FIG. 1, an exemplary structure according to an embodiment of the present disclosure is illustrated. The exemplary structure includes a semiconductor substrate 8. As used herein, a “semiconductor substrate” refers to a substrate that includes at least one semiconductor material portion, i.e., at least one portion of a semiconductor material. The semiconductor substrate 8 includes a substrate semiconductor material layer 9 at least at a top portion thereof. The semiconductor substrate 8 may optionally include at least one additional material layer at a bottom portion thereof. In one embodiment, the semiconductor substrate 8 can be a bulk semiconductor substrate consisting of a semiconductor material (e.g., single crystal silicon wafer), or can be a semiconductor-on-insulator (SOI) substrate including a buried insulator layer (such as a silicon oxide layer) underlying the semiconductor (e.g., silicon) material portion, and a handle substrate underlying the buried insulator layer.

The substrate semiconductor material layer 9 may include a lightly doped semiconductor material portion, on which at least one field effect transistor can be subsequently formed. In one embodiment, the entirety of the semiconductor substrate 8 may be the substrate semiconductor material layer 9. In another embodiment, the substrate semiconductor material layer 9 may comprise an upper portion of the semiconductor substrate 8, such as a doped silicon wafer. The substrate semiconductor material layer 9 may include a lightly doped semiconductor material including electrical dopants of a first conductivity type at an atomic concentration in a range from 1.0×10¹⁴/cm³ to 1.0×10¹⁸/cm³, such as from 1.0×10¹⁵/cm³ to 1.0×10¹⁷/cm³, although lesser and greater atomic concentrations can also be employed. The first conductivity type may be p-type or n-type.

The semiconductor material of the substrate semiconductor material layer 9 can be an elemental semiconductor material (such as silicon) or an alloy of at least two elemental semiconductor materials (such as a silicon-germanium compound semiconductor material), or can be a compound semiconductor material (such as a III-V compound semiconductor material or a II-VI compound semiconductor material), or can be an organic semiconductor material. The thickness of the substrate semiconductor material layer 9 can be in a range from 0.5 mm to 2 mm in case the semiconductor substrate 8 is a bulk semiconductor substrate. In case the semiconductor substrate 8 is a semiconductor-on-insulator substrate, the thickness of the substrate semiconductor material layer 9 may be in a range from 100 nm to 1,000 nm, although lesser and greater thicknesses can also be employed.

A masked ion implantation process can be performed to implant electrical dopants into a surface portion of the substrate semiconductor material layer 9 to form one or more doped wells in the transistor region 100 and/or in the capacitor region 200. The doped wells may comprise p-doped wells and/or n-doped wells. In one embodiment, a substrate doped semiconductor portion 128 that is formed as a doped well in the capacitor region 200 comprises a portion of a bottom electrode of a three-terminal multi-dielectric capacitor.

In a non-limiting exemplary configuration, the substrate doped semiconductor portion 128 may be electrically connected to the substrate semiconductor material layer 9. In one embodiment, the substrate doped semiconductor portion 128 includes electrical dopants of the first conductivity type at an atomic concentration in a range from 1×10¹⁹/cm³ to 5×10²¹/cm³, although lesser and greater atomic concentrations may also be employed. The thickness of the substrate doped semiconductor portion 128 may be in a range from 50 nm to 500 nm, although lesser and greater thicknesses may also be employed.

Optionally, an additional masked ion implantation process may be performed to form at least one doped well (not illustrated) in a surface portion of the transistor region 100. For example, a double well structure or a triple well structure may be provided within an upper portion of the transistor region 100. According to an aspect of the present disclosure, the device regions comprise transistor regions 100 in which a respective field effect transistor is to be subsequently formed and capacitor regions 200 in which a respective capacitor is to be subsequently formed. A transistor region 100 and a capacitor region 200 are illustrated in FIG. 1.

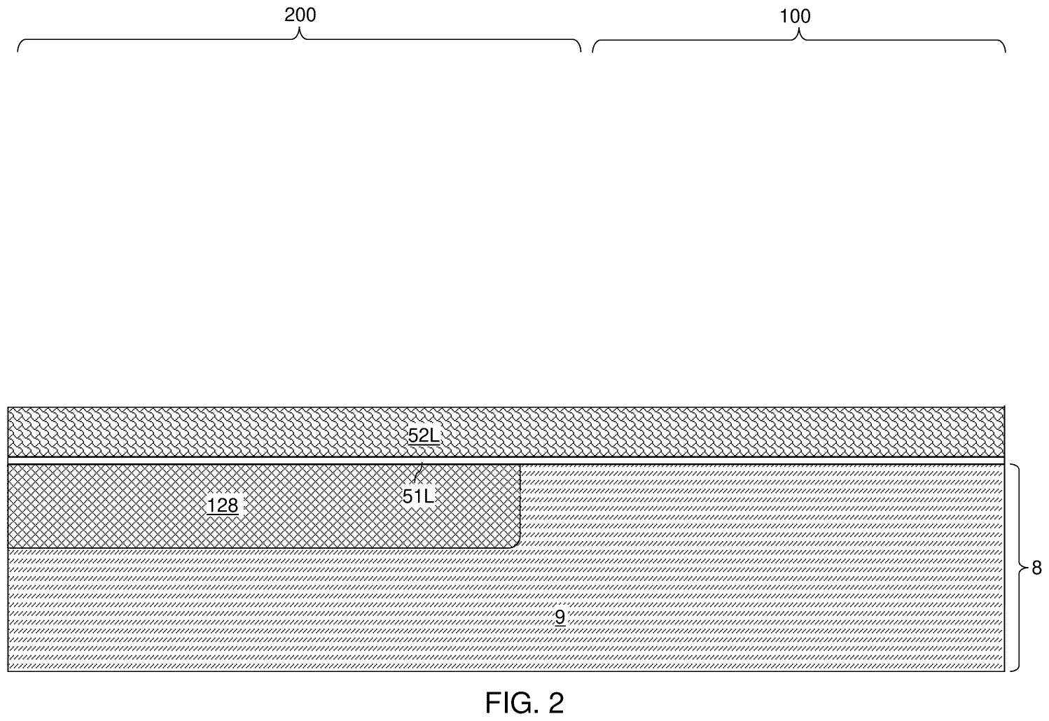

Referring to FIG. 2, a gate dielectric material layer 51L and a gate semiconductor material layer 52L can be sequentially formed over the top surface of the semiconductor substrate 8. The gate dielectric material layer 51L may comprise any gate dielectric material known in the art, such as silicon oxide or silicon oxynitride. The thickness of the gate dielectric material layer 51L may be in a range from 2 nm to 12 nm, such as from 5 nm to 10 nm, although lesser and greater thicknesses may also be employed.

The gate semiconductor material layer 52L comprises a doped semiconductor material, which may be any type of doped semiconductor material in the art. The gate semiconductor material layer 52L may be formed as an undoped semiconductor material layer, and may be subsequently doped by an ion implantation process either globally or locally (employing a masked ion implantation process). Alternatively, the gate semiconductor material layer 52L may be formed as a heavily doped semiconductor material layer by a semiconductor deposition process employing in-situ doping. Generally, each portion of the gate semiconductor material layer 52L located in the transistor region 100 and the capacitor region 200 may be doped with the same or different conductivity type (e.g., p-type or n-type) electrical dopants to function as a middle electrode of a capacitor. For example, the gate semiconductor material layer 52L may comprise a heavily doped polysilicon or amorphous silicon doped with n-type (e.g., phosphorus) dopants at a concentration in a range from 1×10¹⁹/cm³ to 5×10²¹/cm³, although lesser and greater atomic concentrations may also be employed. The thickness of the gate semiconductor material layer 52L may be in a range from 30 nm to 100 nm, such as from 50 nm to 70 nm, although lesser and greater thicknesses may also be employed.

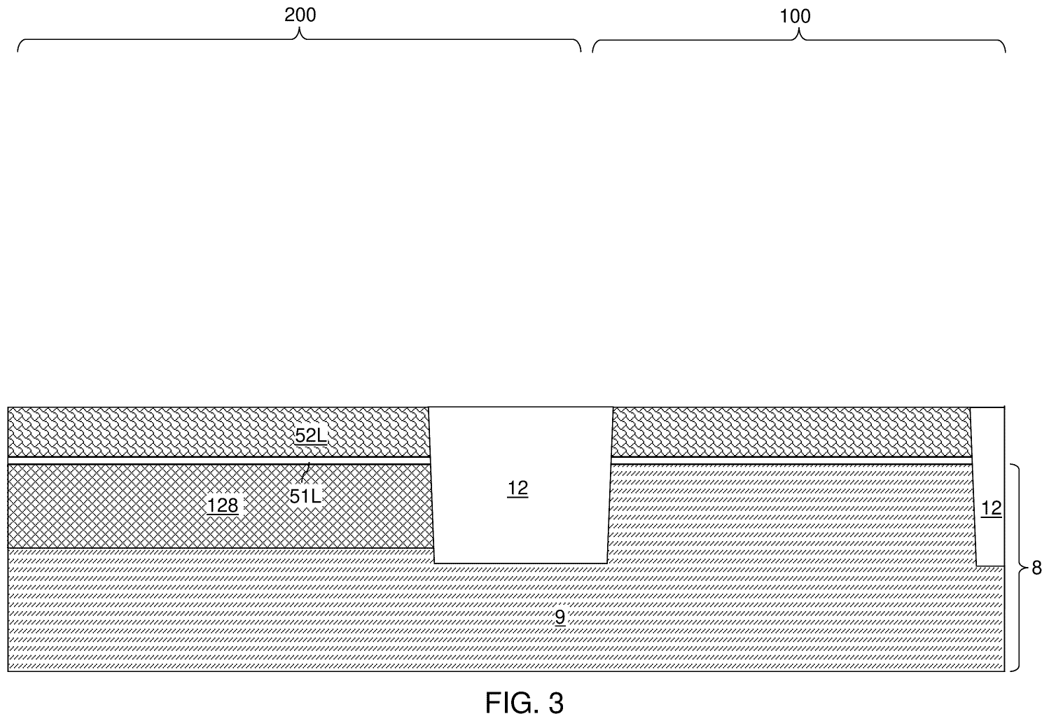

Referring to FIG. 3, shallow trench isolation structures 12 can be formed through the gate semiconductor material layer 52L and the gate dielectric material layer 51L and in the upper portion of the substrate semiconductor material layer 9. The shallow trench isolation structures 12 may laterally surround remaining surface portions of the substrate semiconductor material layer 9 in each device region (100, 200) in which a respective device is to be subsequently formed. In one embodiment, each patterned portion of the gate semiconductor material layer 52L and the gate dielectric material layer 51L in the transistor region 100 and the capacitor region 200 may be laterally surrounded by a respective shallow trench isolation structure 12. In one embodiment, the top surfaces of the shallow trench isolation structures 12 may be formed within, or in proximity to, the horizontal plane including the top surface of the gate semiconductor material layer 52L.

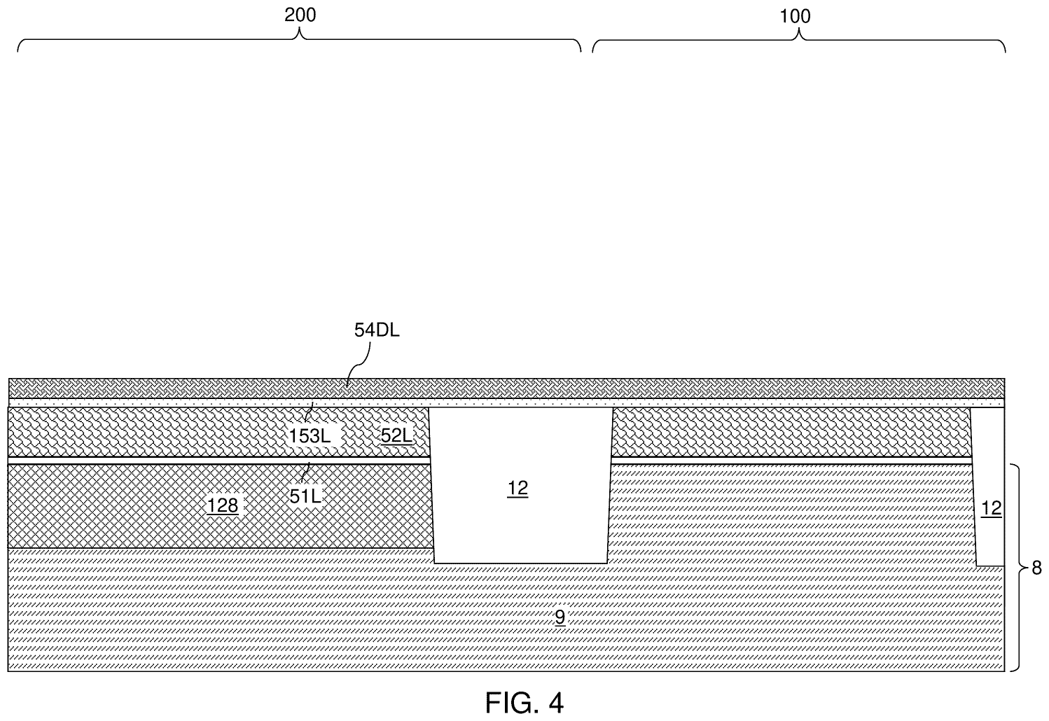

Referring to FIG. 4, a top node dielectric material layer 153L can be formed on the top surfaces of the gate semiconductor material layer 52L and the shallow trench isolation structures 12. The top node dielectric material layer 153L may comprise any capacitor dielectric material known in the art, such as silicon oxide, silicon oxynitride or silicon nitride. For example, the thickness of the top node dielectric material layer 153L may be in a range from 5 nm to 15 nm, such as from 7 nm to 12 nm, although lesser and greater thicknesses may also be employed.

An electrically-doped semiconductor layer 54DL is formed on the top surface of the top node dielectric material layer 153L. The electrically-doped semiconductor layer 54DL may also be referred to as a first electrically-doped semiconductor layer. As used herein, an “electrically-doped” semiconductor layer refers to a semiconductor layer that is doped with electrical dopants, i.e., p-type dopants or n-type dopants, at an atomic concentration greater than 1×10¹⁶/cm³, and preferably greater than 1×10¹⁷/cm³. In one embodiment, the electrically-doped semiconductor layer 54DL may be heavily doped such that a doped polycrystalline semiconductor material that is obtained by annealing the electrically-doped semiconductor layer 54DL has an electrical conductivity greater than 1.0×10⁵ S/cm. The electrically-doped semiconductor layer 54DL comprises an amorphous semiconductor material that is heavily doped with electrical dopants, which may be p-type dopants or n-type dopants. For example, the electrically-doped semiconductor layer 54DL may comprise phosphorus-doped amorphous silicon or a phosphorus-doped amorphous silicon-germanium compound semiconductor material. The atomic concentration of the electrical dopants in the electrically-doped semiconductor layer 54DL may be in a range from 1×10¹⁹/cm³ to 5×10²¹/cm³, although lesser and greater atomic concentrations may also be employed.

The electrically-doped semiconductor layer 54DL may be formed by deposition of an electrically doped semiconductor material employing in-situ doping with an electrical dopant in a deposition chamber employing a chemical vapor deposition process or an atomic layer deposition process. In case the electrically-doped semiconductor layer 54DL comprises p-doped amorphous silicon or n-doped amorphous silicon, the electrically-doped semiconductor layer 54DL may be deposited employing a low pressure chemical vapor deposition process at a deposition temperature in a range from 500 degrees Celsius to 580 degrees Celsius, although lower and higher deposition temperatures may also be employed. A reactant gas, such as silane, dichlorosilane, silicon tetrachloride, etc., may be employed as a precursor gas for the low pressure chemical vapor deposition process. The in-situ doping with the electrical dopant may be effected by flowing a dopant gas concurrently with or alternately with flow of the reactant gas. The dopant gas may comprise, for example, phosphine, arsine, stibine, diborane, etc. The thickness of the electrically-doped semiconductor layer 54DL may be in a range from 10 nm to 60 nm, such as from 15 nm to 30 nm, although lesser and greater thicknesses may also be employed. The electrically-doped semiconductor layer 54DL can be formed directly on the top surface of the top node dielectric material layer 153L.

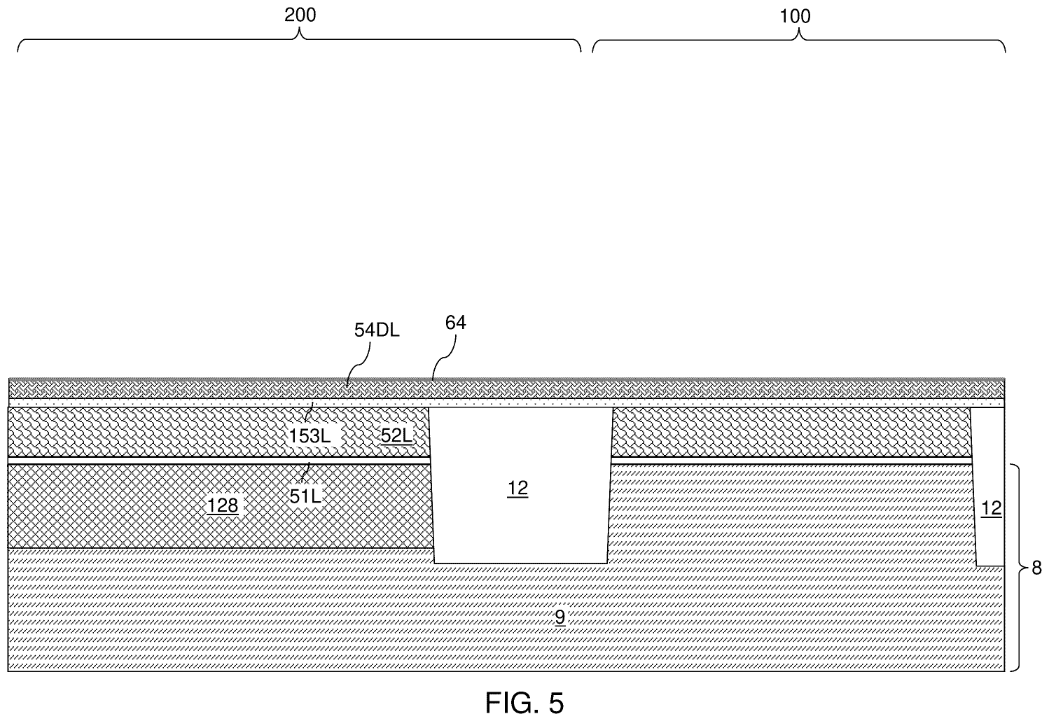

Referring to FIG. 5, an interfacial layer 64 can be formed on the electrically-doped semiconductor layer 54DL. The interfacial layer 64 comprises an oxygen containing interfacial layer. In one embodiment, the interfacial layer 64 comprises a semiconductor oxide interfacial layer, such as a silicon oxide interfacial layer. The silicon oxide interfacial layer may comprise an oxygen rich silicon oxide layer having more than two oxygen atoms for each silicon atom, such as 2.5 to 5 oxygen atoms for each silicon atom. In another embodiment, the interfacial layer 64 comprises one or two monolayers of oxygen atoms located on the top surface of the electrically-doped semiconductor layer 54DL.

In one embodiment, the interfacial layer 64 is formed by oxidation of a top surface portion of the electrically-doped semiconductor layer 54DL. For example, the interfacial layer 64 may be formed by in-situ exposure of the top surface portion of the electrically-doped semiconductor layer 54DL to an oxygen-containing ambient in the deposition chamber employed to deposit the electrically-doped semiconductor layer 54DL. In one embodiment, the temperature of the electrically-doped semiconductor layer 54DL during the in-situ exposure to an oxygen-containing ambient may be the same as the deposition temperature employed to deposit the electrically-doped semiconductor layer 54DL. The oxygen-containing ambient gas may comprise oxygen gas and/or another oxidant gas (e.g., N₂O or water vapor) at a partial pressure in a range from 1 mTorr to 1 Torr, although lesser and greater partial pressures may also be employed. The duration of the in-situ exposure to the oxygen-containing ambient may be in a range from 10 seconds to 600 seconds, although lesser and greater durations may also be employed.

The interfacial layer 64 may have an effective thickness in a range from 0.1 nm to 1.2 nm. Thus, the interfacial layer 64 may be a continuous layer or a discontinuous layer. As used herein, an “effective thickness” of a thin material layer refers to an equivalent thickness that provides the same amount of material. In this case, the effective thickness of the interfacial layer 64 is the ratio of a surface density of the oxygen atoms within the interfacial layer 64 to the atomic density of oxygen atoms in a bulk silicon oxide material, i.e., the total amount of oxygen atoms within the interfacial layer 64 per unit area to the total amount of oxygen atoms within a silicon oxide material per unit volume. The atomic density of oxygen atoms in silicon dioxide is about 5.31×10²² atoms/cm³. Thus, if the interfacial layer 64 has an areal oxygen atom density of 5.31×10¹⁵ atoms/cm, the thickness of the interfacial layer 64 is 1 nm. If the interfacial layer 64 has an areal oxygen atom density of 5.31×10¹⁴ atoms/cm, the thickness of the interfacial layer 64 is 0.1 nm. Thus, the effective thickness of the interfacial layer 64 can be defined by the oxygen content within the interfacial layer 64. Generally, the interfacial layer 64 is similar in nature to native silicon oxide known in the art, and the thickness of the interfacial layer 64 tends to saturate within the temperature range for deposition of the electrically-doped semiconductor portion 54D. In one embodiment, the thickness of the interfacial layer 64 is in a range from 0.3 nm to 1 nm. The interfacial layer 64 contacts a top surface of the electrically-doped semiconductor portion 54D.

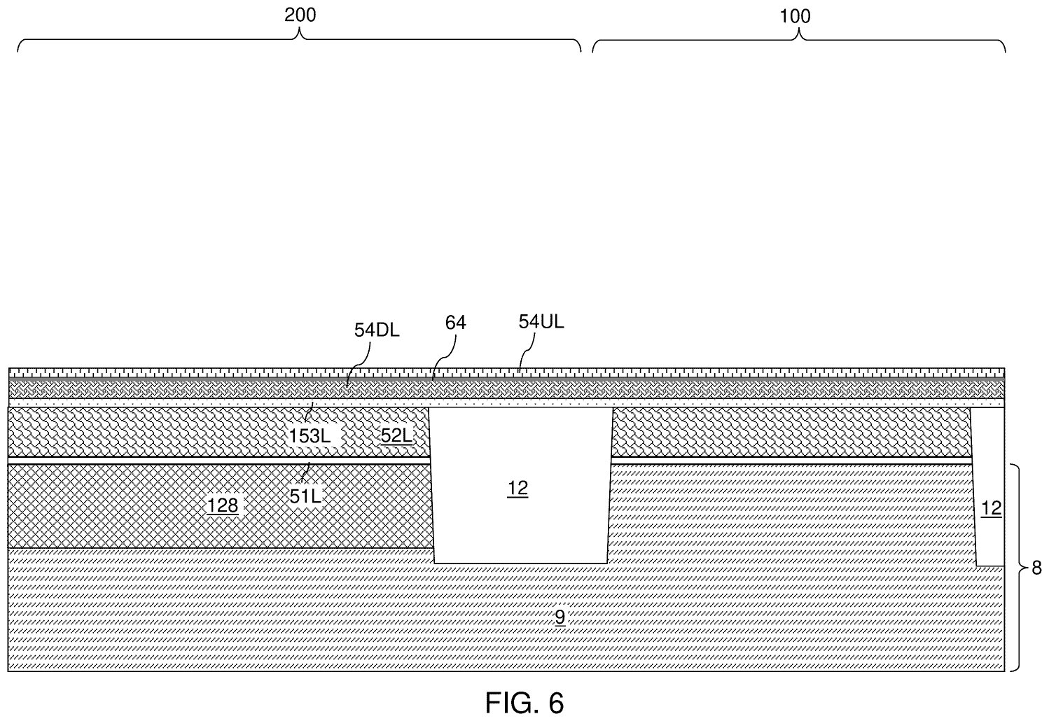

Referring to FIG. 6, an electrically-undoped semiconductor layer 54UL is formed on the top surface of the interfacial layer 64. The electrically-undoped semiconductor layer 54UL may also be referred to as a first electrically-undoped semiconductor layer in the claims. As used herein, an “electrically-undoped” semiconductor layer refers to a semiconductor layer that is free of n-type and p-type electrical dopants, or includes electrical dopants at an atomic concentration less than 1×10¹⁶/cm³, and preferably less than 1×10¹⁴/cm³. Generally, an electrically-undoped semiconductor layer can be deposited by avoiding any intentional electrical doping during a deposition process, for example, by not flowing any dopant gas during or after the deposition process that deposits a semiconductor material.

In one embodiment, the electrically-undoped semiconductor layer 54UL may consist essentially of an amorphous intrinsic semiconductor material, such as intrinsic amorphous silicon. The intrinsic amorphous silicon includes boron, phosphorus, arsenic and antimony at an atomic concentration less than 1×10¹⁶/cm³, preferably less than 1×10¹⁵/cm³, and even more preferably less than 1×10¹⁴/cm³.

In an alternative embodiment, the electrically-undoped semiconductor portion 54U may comprise an amorphous semiconductor material that is doped with atoms of at least one electrically inactive dopant at an atomic concentration in a range from 1×10¹⁷/cm³ to 5×10²¹/cm³. As used herein, an electrically inactive dopant refers to a dopant that does not generate any charge carrier in the semiconductor material. An electrically inactive dopant may affect structural characteristics of the semiconductor material. In one embodiment, the at least one electrically inactive dopant may comprise carbon.

Generally, the electrically-undoped semiconductor layer 54UL may be formed by deposition of a semiconductor material in the deposition chamber that is employed to form the electrically-doped semiconductor layer 54DL and the interfacial layer 64. In this case, there is no need to transfer the semiconductor substrate 8 out of the deposition chamber until after deposition of the electrically-undoped semiconductor layer 54UL. The electrically-undoped semiconductor layer 54UL may be deposited employing a low pressure chemical vapor deposition process or an atomic layer deposition process at a deposition temperature in a range from 500 degrees Celsius to 580 degrees Celsius, although lower and higher deposition temperatures may also be employed. A reactant gas such as silane, dichlorosilane, silicon tetrachloride, etc., may be employed as a precursor gas for the low pressure chemical vapor deposition process. The thickness of the electrically-undoped semiconductor layer 54UL may be in a range from 5 nm to 20 nm, such as from 7 nm to 15 nm, although lesser and greater thicknesses may also be employed. The electrically-undoped semiconductor layer 54UL can be formed directly on the top surface of the interfacial layer 64.

In case the electrically-undoped semiconductor layer 54UL comprises the at least one electrically inactive dopant, the electrically-undoped semiconductor layer 54UL may be formed by deposition of an amorphous semiconductor material employing in-situ doping with the at least one electrically inactive dopant (such as carbon) in the deposition chamber employing a chemical vapor deposition process. The in-situ doping with the electrical dopant may be accomplished by flowing a dopant gas concurrently with or alternately with flow of the reactant gas. In case the at least one electrically inactive dopant comprises carbon, the dopant gas may comprise, for example, methane, ethane, propane, ethylene, propylene, acetylene, etc.

The electrically-undoped semiconductor layer 54UL is formed as a second amorphous semiconductor material layer, which may optionally include atoms of an electrically inactive dopant. The interfacial layer 64 contacts a top surface of the electrically-doped semiconductor layer 54DL and a bottom surface of the electrically-undoped semiconductor layer 54UL. The layer stack including the top node dielectric material layer 153L, the electrically-doped semiconductor layer 54DL, the interfacial layer 64, and the electrically-undoped semiconductor layer 54UL is herein referred to as a capacitor material layer stack (153L, 54DL, 64, 54UL).

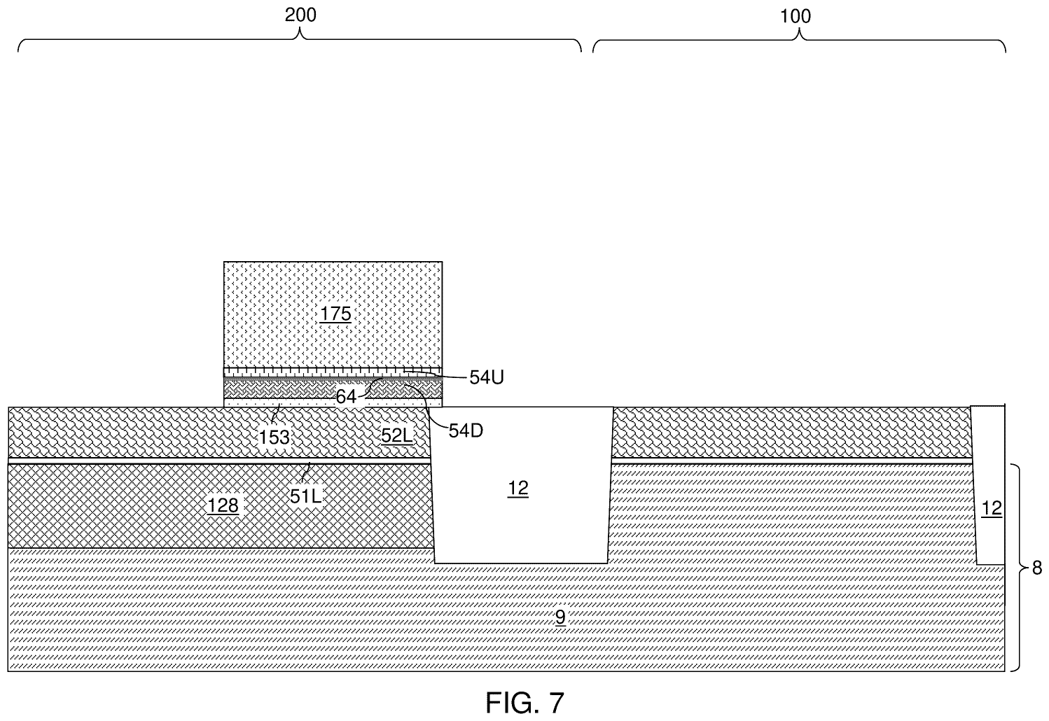

Referring to FIG. 7, a first photoresist layer 175 can be applied over the capacitor material layer stack (153L, 54DL, 64, 54UL), and can be lithographically patterned to cover an area within the capacitor region 200 without covering the area of the transistor region 100. For example, the patterned first photoresist layer 175 can cover part of the capacitor region 200 adjacent to the shallow trench isolation structures 12. The first photoresist layer 175 covers a portion of the gate semiconductor material layer 52L and a neighboring portion of the shallow trench isolation structures 12. An etch process can be performed to etch the materials of the capacitor material layer stack (153L, 54DL, 64, 54UL) from the transistor region 100 while preventing removal of the covered portions of the capacitor material layer stack (153L, 54DL, 64, 54UL) from the capacitor region 200. The etch process may comprise a series of etch steps for sequentially etching the materials of the capacitor material layer stack (153L, 54DL, 64, 54UL) from top to bottom. The terminal etch step of the etch process may etch the material of the top node dielectric material layer 153L selectively to the material of the gate semiconductor material layer 52L. The series of etch steps may comprise at least one anisotropic etch process (such as at least one reactive ion etch process) and/or at least one isotropic etch process (such as at least one wet etch process). The first photoresist layer 175 can be subsequently removed, for example, by ashing.

A patterned remaining portion of the electrically-undoped semiconductor layer 54UL that underlies the first photoresist layer 175 comprises an electrically-undoped semiconductor portion 54U. Unmasked portions of the interfacial layer 64 that are not covered by the first photoresist layer 175 can be removed by the etch process. A patterned remaining portion of the electrically-doped semiconductor layer 54DL that underlies the first photoresist layer 175 comprises an electrically-doped semiconductor portion 54D. A patterned portion of the top node dielectric material layer 153L comprises a top node dielectric 153.

Sidewalls of the electrically-undoped semiconductor portion 54U, the interfacial layer 64 (as patterned by the etch process), the electrically-doped semiconductor portion 54D, and the top node dielectric 153 may be vertically coincident among one another. As used herein, two or more surfaces are vertically coincident if the two or more surfaces are located within a same vertical plane and if the two or more surfaces overlie or underlie one another. In one embodiment, a sidewall of the electrically-undoped semiconductor portion 54U, a sidewall of the interfacial layer 64, a sidewall of the electrically-doped semiconductor portion 54D, and a sidewall of the top node dielectric 153 can be formed entirely within the area of a shallow trench isolation structure 12 in a top view. In one embodiment, a sidewall of the electrically-undoped semiconductor portion 54U, a sidewall of the interfacial layer 64, a sidewall of the electrically-doped semiconductor portion 54D, and a sidewall of the top node dielectric 153 can extend over the shallow trench isolation structure 12, but is located within the outer sidewall boundary of the shallow trench isolation structure 12 in the top view.

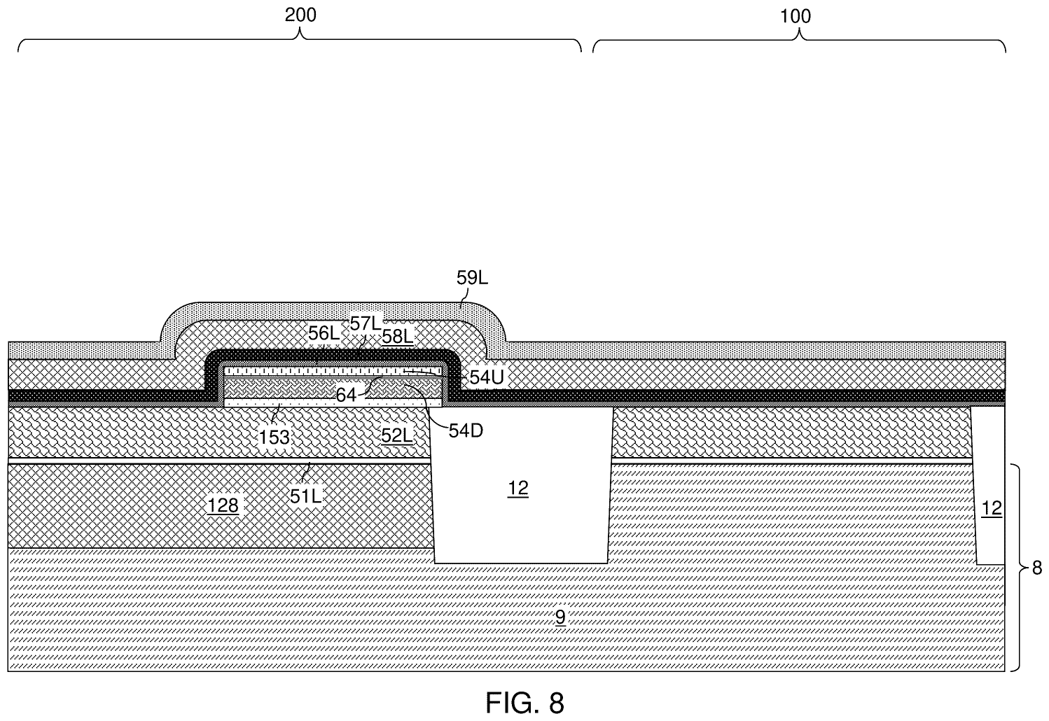

Referring to FIG. 8, a capping layer stack (56L, 57L, 58L, 59L) including a first electrode metallic material layer 56L, a second electrode metallic material layer 57L, a third electrode metallic material layer 58L, and an optional capping dielectric layer 59L can be deposited over the remaining portions of the capacitor material layer stack (153L, 54DL, 64, 54UL) in the capacitor region 200 and over the gate semiconductor material layer 52L in the transistor region 100. A portion of the capping layer stack (56L, 57L, 58L, 59L) overlying the stack of the electrically-undoped semiconductor portion 54U, the interfacial layer 64, the electrically-doped semiconductor portion 54D, and the top node dielectric 153 may form a bump structure that protrudes above a horizontal plane including a portion of a top surface of the capping dielectric layer 59L located in the transistor region 100.

The first electrode metallic material layer 56L is deposited directly on a top surface of the first portion of the gate semiconductor material layer 52L in the transistor region 100, and directly on a top surface of the electrically-undoped semiconductor portion 54U in the capacitor region 200. In one embodiment, the first electrode metallic material layer 56L comprises and/or consists essentially of a transition metal, such as titanium. The thickness of the horizontally-extending portions of the first electrode metallic material layer 56L may be in a range from 1 nm to 3 nm, such as from 1.2 nm to 2 nm, although lesser and greater thicknesses may also be employed.

The second electrode metallic material layer 57L comprises a second metallic nitride material that can function as a diffusion barrier layer and suppress diffusion of metal atoms from the third electrode metallic material layer 58L. For example, the second electrode metallic material layer 57L may consist essentially of titanium nitride, tantalum nitride, tungsten nitride, or molybdenum nitride. In one embodiment, the second electrode metallic material layer 57L consists essentially of titanium nitride. The thickness of the second electrode metallic material layer 57L may be greater than the thickness of the first electrode metallic material layer 56L. For example, the thickness of the second electrode metallic material layer 57L may be in a range from 4 nm to 15 nm, such as from 6 nm to 10 nm, although lesser and greater thicknesses may also be employed.

The third electrode metallic material layer 58L comprises a transition metal having a high electrical conductivity. In one embodiment, the third electrode metallic material layer 58L may comprise a refractory metal such as tungsten, molybdenum, or tantalum. The thickness of the third electrode metallic material layer 58L may be in a range from 15 nm to 60 nm, such as from 20 nm to 50 nm, although lesser and greater thicknesses may also be employed.

The optional capping dielectric layer 59L comprises a diffusion barrier dielectric material such as silicon oxide, silicon oxynitride and/or silicon nitride. For example, the optional capping dielectric layer 59L may comprise a lower silicon oxide sublayer and an upper silicon nitride sublayer. The thickness of the capping dielectric layer 59L may be in a range from 50 nm to 120 nm, such as from 70 nm to 100 nm, although lesser and greater thicknesses may also be employed.

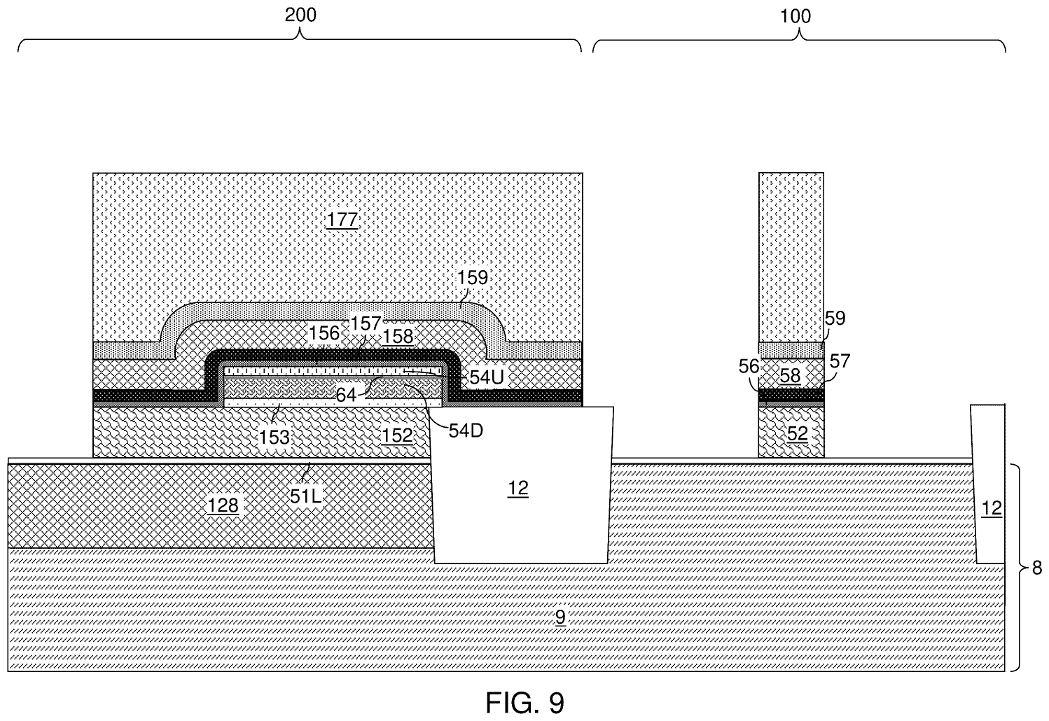

Referring to FIG. 9, a second photoresist layer 177 can be formed over the capping dielectric layer 59L, and can be lithographically patterned to cover an area in which a capacitor is to be subsequently formed in the capacitor region 200, and to cover an area in which a gate electrode is to be subsequently formed in the transistor region 100. An anisotropic etch process can be performed to transfer the pattern in the second photoresist layer 177 through the capping layer stack (56L, 57L, 58L, 59L), and the gate semiconductor material layer 52L. The anisotropic etch process stops on the gate dielectric material layer 51L.

A first patterned portion of the capping dielectric layer 59L in the transistor region 100 comprises a gate capping dielectric 59, a first patterned portion of the third electrode metallic material layer 58L in the transistor region 100 comprises a third gate metallic layer 58, a first patterned portion of the second electrode metallic material layer 57L in the transistor region 100 comprises a second gate metallic layer 57, a first patterned portion of the first electrode metallic material layer 56L in the transistor region 100 comprises a first gate metallic layer 56, and a first patterned portion of the gate semiconductor material layer 52L in the transistor region 100 comprises a doped semiconductor gate electrode 52.

A contiguous combination of patterned portions of the capping layer stack (56L, 57L, 58L, 59L) and the doped semiconductor gate electrode 52 in the transistor region 100 comprises a gate electrode (52, 56, 57, 58) of a transistor. Thus, the gate electrode (52, 56, 57, 58) comprises a doped semiconductor gate electrode 52 and at least one gate metallic layer (56, 57, 58), which may include a first gate metallic layer 56, a second gate metallic layer 57, and a third gate metallic layer 58. In one embodiment, a top surface of the doped semiconductor gate electrode 52 contacts a bottom surface of the first gate metallic layer 56. The second gate metallic layer 57 is located between and contacts the first gate metallic layer 56 and the third gate metallic layer 58. The entirety of the at least one gate metallic layer (56, 57, 58) comprises a metallic gate electrode (56, 57, 58), which has a same set of component layers as the at least one electrode metallic layer (156, 157, 158) of a capacitor to be subsequently formed.

A second patterned portion of the capping dielectric layer 59L in the capacitor region 200 comprises a capacitor capping dielectric 159, a second patterned portion of the third electrode metallic material layer 58L in the capacitor region 200 comprises a third electrode metallic layer 158, a second patterned portion of the second electrode metallic material layer 57L in the capacitor region 200 comprises a second electrode metallic layer 157, a second patterned portion of the first electrode metallic material layer 56L in the capacitor region 200 comprises a first electrode metallic layer 156, and a second patterned portion of the gate semiconductor material layer 52L in capacitor region 200 comprises a middle electrode 152, which is also referred to as a middle doped semiconductor portion.

The middle electrode 152 may have a greater lateral extent than the top node dielectric 153. The first gate metallic layer 56 and the first electrode metallic layer 156 have the same material composition and have a same thickness. In one embodiment, the first gate metallic layer 56 and the first electrode metallic layer 156 consist essentially of titanium. The third gate metallic layer 58 and the third electrode metallic layer 158 have a same material composition (e.g., tungsten) and have a same thickness. The second gate metallic layer 57 and the second electrode metallic layer 157 have a same material composition (e.g., TiN) and a same thickness. The second photoresist layer 177 can be subsequently removed, for example, by ashing.

In one embodiment, the at least one electrode metallic layer (156, 157, 158) contacts a top surface of the electrically-undoped semiconductor portion 54U. In one embodiment, the at least one electrode metallic layer (156, 157, 158) comprises: a first electrode metallic layer 156 consisting essentially of titanium, and contacting the electrically-undoped semiconductor portion 54U; and a second electrode metallic layer 157 comprising a conductive metallic nitride material and contacting the first electrode metallic layer 156.

In one embodiment, the first electrode metallic layer 156 comprises: a first horizontally-extending portion that overlies the electrically-undoped semiconductor portion 54U; a vertically-extending portion that contacts sidewalls of the electrically-undoped semiconductor portion 54U, the interfacial layer 64, and the electrically-doped semiconductor portion 54D; and a second horizontally-extending portion that is adjoined to a bottom end of the vertically-extending portion and does not have an areal overlap in a plan view with the electrically-undoped semiconductor portion 54U.

In one embodiment, the shallow trench isolation structures 12 can be embedded in the semiconductor substrate 8. A shallow trench isolation structure 12 can contact sidewalls of a bottom electrode as embodied as a substrate doped semiconductor portion 128, the bottom node dielectric 151, and the middle electrode 152. A bottom surface of the first electrode metallic layer 156 contacts a top surface of the shallow trench isolation structure 12.

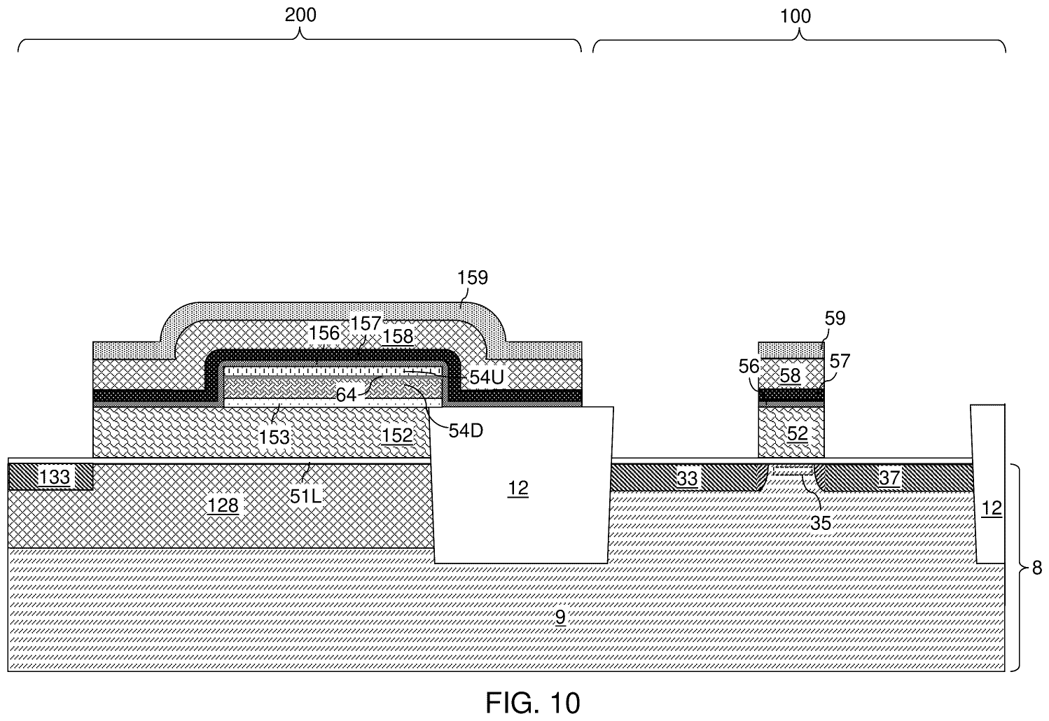

Referring to FIG. 10, a masked or unmasked ion implantation process can be performed to form a source extension region 33 and a drain extension region 37 in the transistor region 100. The gate electrode (52, 56, 57, 58) and the gate capping dielectric 59 may be employed as self-aligned etch mask structures during the ion implantation process. A channel region 35 is formed between the source extension region 33 and the drain extension region 37. A lightly doped contact region 133 is also formed in the exposed portion of the substrate doped semiconductor portion 128 in the capacitor region 200. The combination of the substrate doped semiconductor portion 128 and the lightly doped contact region 133 constitutes a bottom electrode (128, 133).

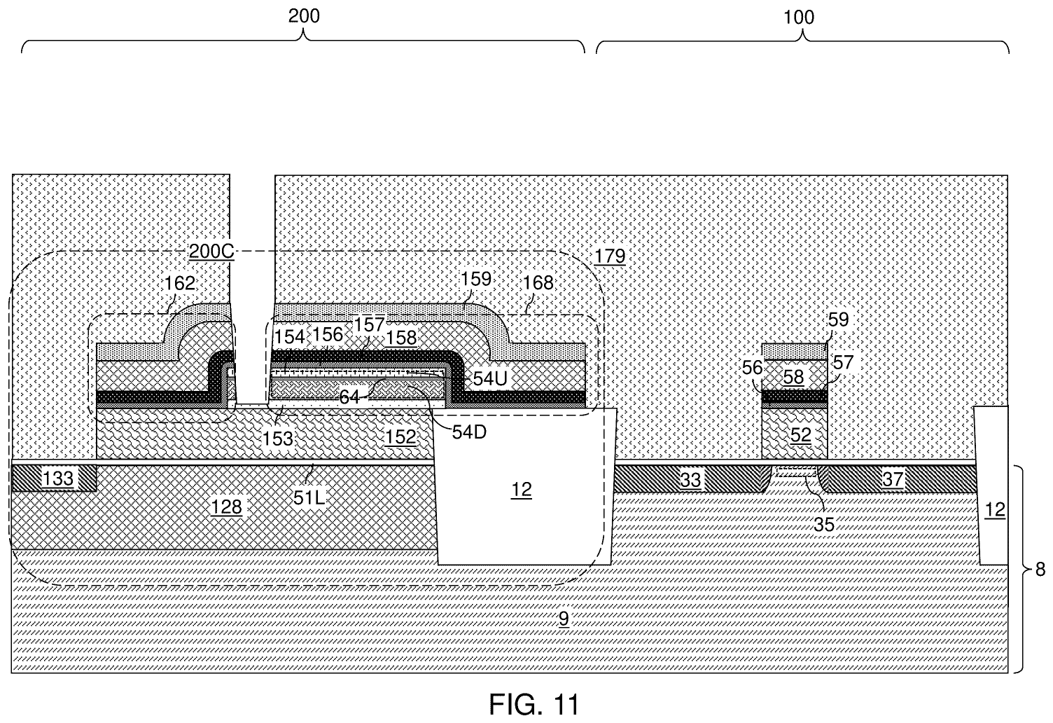

Referring to FIG. 11, a third photoresist layer 179 can be applied over the gate capping dielectric 59 and the capacitor capping dielectric 159, and can be lithographically patterned to form an opening that laterally extends along vertical interfaces between the at least one electrode metallic layer (156, 157, 158) and the stack of the electrically-undoped semiconductor portion 54U, the interfacial layer 64, the electrically-doped semiconductor portion 54D, and the top node dielectric 153. The opening in the third photoresist layer 179 can be formed within a peripheral area of the stack of the electrically-undoped semiconductor portion 54U, the interfacial layer 64, the electrically-doped semiconductor portion 54D, and the top node dielectric 153 that overlies the middle electrode 152, and may extend into an adjacent portion of the shallow trench isolation structures 12. Generally, a portion of the third electrode metallic layer 158 that does not underlie the opening in the third photoresist layer continuously extends from above a shallow trench isolation structure 12 in contact with the middle electrode 152 to an area that overlies a predominant fraction (i.e., more than 50%) of the area of the stack of the electrically-undoped semiconductor portion 54U, the interfacial layer 64, the electrically-doped semiconductor portion 54D, and the top node dielectric 153.

An anisotropic etch process can be performed to transfer the pattern of the opening in the third photoresist layer 179 through the capacitor capping dielectric 159, the third electrode metallic layer 158, the second electrode metallic layer 157, the first electrode metallic layer 156, the electrically-undoped semiconductor portion 54U, the interfacial layer 64, and the electrically-doped semiconductor portion 54D, and optionally into a portion of the top node dielectric 153. The stack including the capacitor capping dielectric 159, the third electrode metallic layer 158, the second electrode metallic layer 157, the first electrode metallic layer 156, the electrically-undoped semiconductor portion 54U, the interfacial layer 64, and the electrically-doped semiconductor portion 54D is divided into two contiguous portions that are laterally spaced from each other by a trench that underlies the opening in the third photoresist layer 179. A contiguous combination of patterned portions of the stack of the third electrode metallic layer 158, the second electrode metallic layer 157, the first electrode metallic layer 156, the electrically-undoped semiconductor portion 54U, the interfacial layer 64, and the electrically-doped semiconductor portion 54D that includes a predominant fraction of the materials of the electrically-undoped semiconductor portion 54U, the interfacial layer 64, and the electrically-doped semiconductor portion 54D as provided after the processing steps of FIG. 10 constitutes a top electrode 168 of a capacitor. Another contiguous combination of patterned portions of the stack of the third electrode metallic layer 158, the second electrode metallic layer 157, the first electrode metallic layer 156, the electrically-undoped semiconductor portion 54U, the interfacial layer 64, and the electrically-doped semiconductor portion 54D that does not include, or includes a minor fraction of, the materials of the electrically-undoped semiconductor portion 54U, the interfacial layer 64, and the electrically-doped semiconductor portion 54D as provided after the processing steps of FIG. 10 constitutes a middle electrode contact structure 162 of the capacitor.

A segment of a top surface of the substrate doped semiconductor portion 128 can be physically exposed. In one embodiment, the doped semiconductor gate electrode 52 and the middle electrode 152 have a same height and a same material composition (e.g., heavily n-type doped polysilicon). The combination of the electrically-undoped semiconductor portion 54U, the interfacial layer 64, and the electrically-doped semiconductor portion 54D within the top electrode 168 is herein referred to as a semiconductor top electrode 154. The set of all electrode metallic layers (156, 157, 158) within the top electrode 168 is herein referred to as a metallic top electrode (156, 157, 158). Thus, the top electrode 168 comprises a stack of a semiconductor top electrode 154 and a metallic top electrode (156, 157, 158).

The middle electrode contact structure 162 comprises a set of minor patterned portions of the at least one electrode metallic layer (156, 157, 158) as provided after the processing steps of FIG. 10 and prior to the processing steps of FIG. 11. The middle electrode contact structure 162 may optionally comprise minor patterned portions of the electrically-undoped semiconductor portion 54U, the interfacial layer 64, and the electrically-doped semiconductor portion 54D as provided after the processing steps of FIG. 10 and prior to the processing steps of FIG. 11.

A capacitor 200C is formed, which comprises a bottom electrode (128, 133), a bottom node dielectric 151 (i.e., portion of the gate dielectric material layer 51L which has an areal overlap with the bottom electrode (128, 133)), a middle electrode 152 (which is also referred to as a middle doped semiconductor portion), a top node dielectric 153, a top electrode 168, and a middle electrode contact structure 162. The top electrode (154, 156, 157, 158) comprises, from bottom to top, an electrically-doped semiconductor portion 54D, an interfacial layer 64, an electrically-undoped semiconductor portion 54U, and at least one electrode metallic layer (156, 157, 158). The third photoresist layer 179 can be subsequently removed, for example, by ashing.

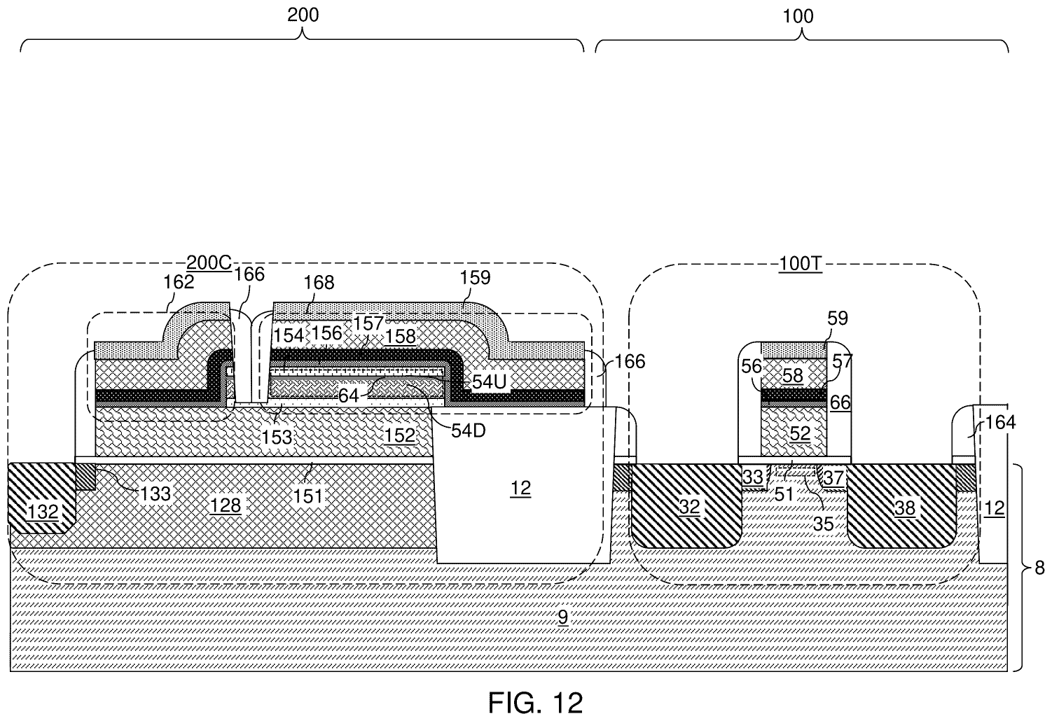

Referring to FIG. 12, at least one dielectric spacer material layer (such as silicon oxide and/or silicon nitride) can be conformally deposited and anisotropically etched to form various dielectric spacers (66, 166, 164). A dielectric gate spacer 66 is formed around the gate electrode (52, 56, 57, 58). A dielectric capacitor spacer 166 is formed around the capacitor capping dielectrics 159, the top electrode 168, the middle electrode contact structure 162, the top node dielectric 153 and the middle electrode 152. The gate dielectric material layer 51L is also patterned during the step of anisotropically etching the dielectric spacer material layer to form a gate dielectric 51 between the semiconductor substrate 8 and the gate electrode (52, 56, 57, 58) in the transistor region 100, and to form a bottom node dielectric 151 between the semiconductor substrate 8 and the middle electrode 152 in the capacitor region 200. Additional dielectric spacers 164 can be formed around additional structures such as sidewalls of the shallow trench isolation structures 12. The dielectric gate spacer 66, the dielectric capacitor spacer 166, and the additional dielectric spacers 164 comprise a same dielectric material, and may have the same lateral width (e.g., between a respective inner sidewall and a respective outer sidewall).

A masked or unmasked ion implantation process can be performed to form a deep source region 32 and a deep drain region 38. A heavily doped contact region 132 is also formed in the exposed portion of the lightly doped contact region 133 and the substrate doped semiconductor portion 128 in the capacitor region 200. The dielectric gate spacer 66, the gate electrode (52, 56, 57, 58), and the gate capping dielectric 59 may be employed as self-aligned etch mask structures during the masked ion implantation process. The combination of the source extension region 33 and the deep source region 32 constitutes a source region (32, 33). The combination of the drain extension region 37 and the deep drain region 38 constitutes a drain region (37, 38). A channel region 35 is located in the semiconductor substrate 8 between the source region (32, 33) and the drain region (37, 38).

A field effect transistor 100T is formed in the transistor region 100. The field effect transistor 100T is located on a first portion of the semiconductor substrate 8, and comprises a gate dielectric 51 including a first portion of a first dielectric material and a gate electrode (52, 56, 57, 58) comprising, from bottom to top, the doped semiconductor gate electrode 52 comprising a first portion of a gate semiconductor material, the first gate metallic layer 56, the second gate metallic layer 57, and the third gate metallic layer 58.

An optional anneal process can be performed at an elevated temperature after the ion implantation processes that form the source region (32, 33) and the drain region (37, 38) to convert the amorphous semiconductor material portions within the capacitor material layer stack (153L, 54DL, 64, 54UL) into polycrystalline semiconductor material portions and to electrically activate the electrical dopants in the semiconductor top electrode 154, the source region (32, 33), the drain region (37, 38), the heavily doped contact region 132, the lightly doped contact region 133, and the substrate doped semiconductor portion 128. The anneal process crystallizes the first amorphous semiconductor material (e.g., amorphous silicon) of the electrically-doped semiconductor portion 54D into a crystalline electrically-doped semiconductor material, which may be a polycrystalline conductive semiconductor material (e.g., heavily doped polysilicon) having electrical conductivity greater than 1.0×10⁵ S/m. Further, the anneal process crystallizes the second amorphous semiconductor material (e.g., amorphous silicon) of the electrically-undoped semiconductor portion 54U into a crystalline electrically-doped semiconductor material, which may be a polycrystalline semiconducting material (e.g., polysilicon) having electrical conductivity in a range from 1.0×10⁻⁶ S/m to 1.0×10⁵ S/m, and typically in a range from 1.0×10⁻² S/m to 1.0×10² S/m.

In one embodiment, the electrically-doped semiconductor portion 54D after the anneal process has a first columnar crystalline structure containing first grain boundaries that extend predominantly along a vertical direction. Since most surfaces of the grain boundaries extend vertically or at a small angle relative to the vertical direction, the average of the cosine of the angle for the grain boundaries is at a maximum relative to an upward vertical direction or relative to a downward vertical direction. The electrically-undoped semiconductor portion 54U after the anneal process has a second columnar crystalline structure containing second grain boundaries that extend predominantly along a vertical direction. The average lateral dimension of the grains of the electrically-doped semiconductor portion 54D may be in a range from 50% to 200% of the respective thickness of the electrically-doped semiconductor portion 54D. The average lateral dimension of the grains of the electrically-undoped semiconductor portion 54U may be in a range from 50% to 200% of the respective thickness of the electrically-undoped semiconductor portion 54U.

The interfacial layer 64 contacts a top surface of the electrically-doped semiconductor portion 54D, and a bottom surface of the electrically-undoped semiconductor portion 54U. According to an aspect of the present disclosure, the interfacial layer 64 blocks and/or suppresses propagation of grain boundaries therethrough. Thus, bottom edges of the second grain boundaries of the electrically-undoped semiconductor portion 54U are randomly offset relative to top edges of the first grain boundaries of the electrically-doped semiconductor portion 54D. The offset in the grain boundaries reduces or prevents diffusion of titanium from the first electrode metallic layer 157 into the electrically-doped semiconductor portion 54D. The reduction or elimination of titanium diffusion improves the TDDB of the capacitor 200C.

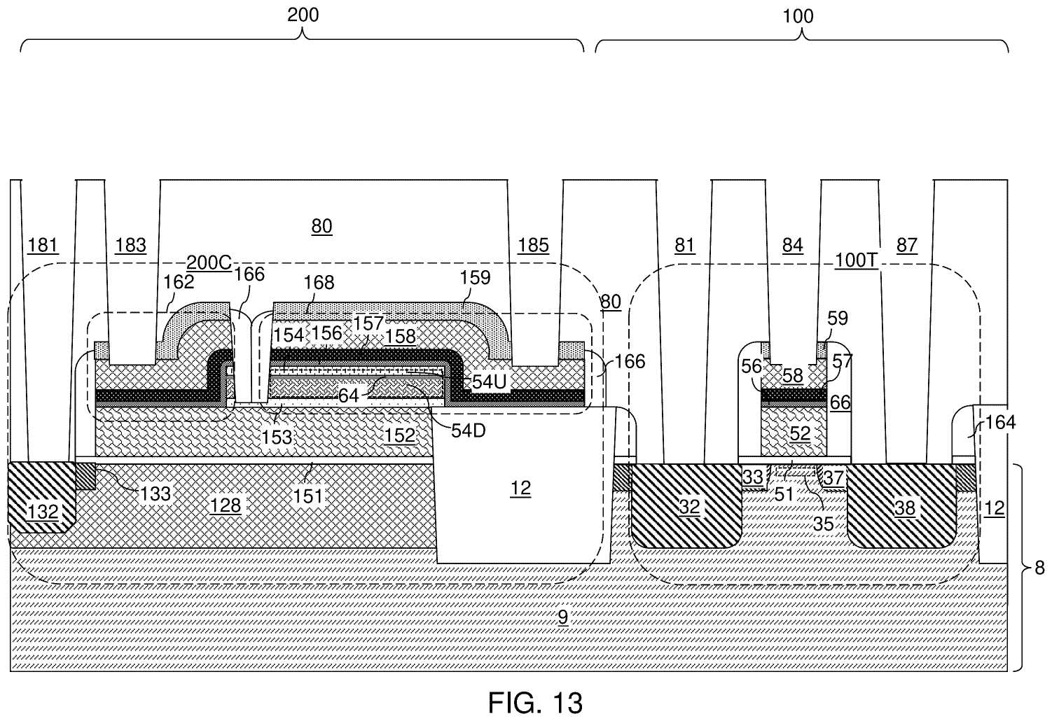

Referring to FIG. 13, a contact-level dielectric layer 80 can be formed over the field effect transistor 100T and the capacitor 200C. The top surface of the contact-level dielectric layer 80 may be planarized as needed, for example, by performing a chemical mechanical polishing process. Contact via cavities (81, 84, 87, 181, 183, 185) can be formed through the contact-level dielectric layer 80. The contact via cavities (81, 84, 87, 181, 183, 185) may comprise a source contact via cavity 81 that is formed on the deep source region 32, a gate contact via cavity 84 that is formed on the third gate metallic layer 58 of the gate electrode (52, 56, 57, 58), a drain contact via cavity 87 that is formed on the deep drain region 38, a bottom electrode contact via cavity 181 that is formed the substrate doped semiconductor portion 128, a middle electrode contact via cavity 183 that is formed on the middle electrode contact structure 162, and a top electrode contact via cavity 185 that is formed on the top electrode 168.

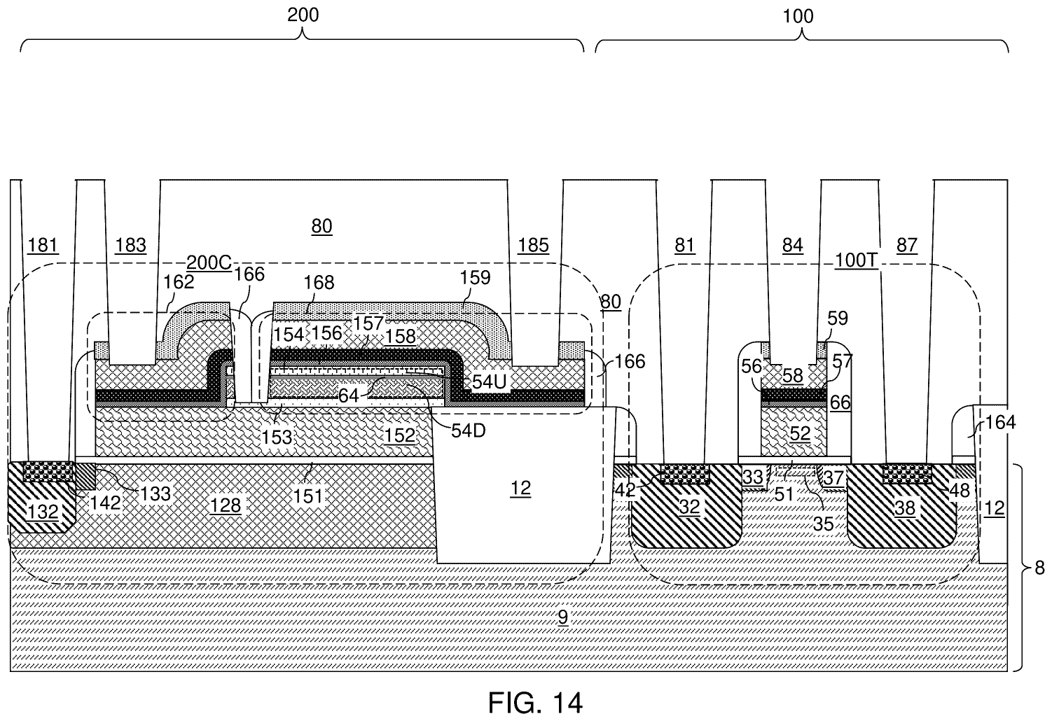

Referring to FIG. 14, various metal-semiconductor alloy (e.g., metal silicide) regions (42, 48, 142) can optionally be formed on physically exposed surfaces of semiconductor material portions, which include physically exposed surfaces of the deep source region 32, the deep drain region 38, and the heavily doped contact region 132 of the substrate doped semiconductor portion 128. Generally, a metal layer that reacts with the semiconductor materials of the deep source region 32, the deep drain region 38, and the heavily doped contact region 132 of the substrate doped semiconductor portion 128 can be deposited at the bottom of the contact via cavities (81, 84, 87, 181, 183, 185). The metal may comprise any silicide forming metal, such as Ti, Pd, Ni, Co, W, Ta, Mo, etc. An anneal process can be performed to induce formation of metal-semiconductor alloy material portions (e.g., metal silicide portions), such as a silicide portions of a metal selected from Ti, Pd, Ni, Co, W, Ta and/or Mo. Unreacted portions of the metal layer can be removed by performing a wet etch process that etches the remaining portion of the metal layer selective to the metal-semiconductor materials. Various metal-semiconductor alloy regions (42, 48, 142) remains after selective removal of the unreacted portions of the metal layer. The various metal-semiconductor alloy regions (42, 48, 142) may comprise a source metal-semiconductor alloy region 42, a drain metal-semiconductor alloy region 48, an electrode metal-semiconductor alloy region 142. Alternatively, formation of the metal-semiconductor alloy regions (42, 48, 142) may be omitted.

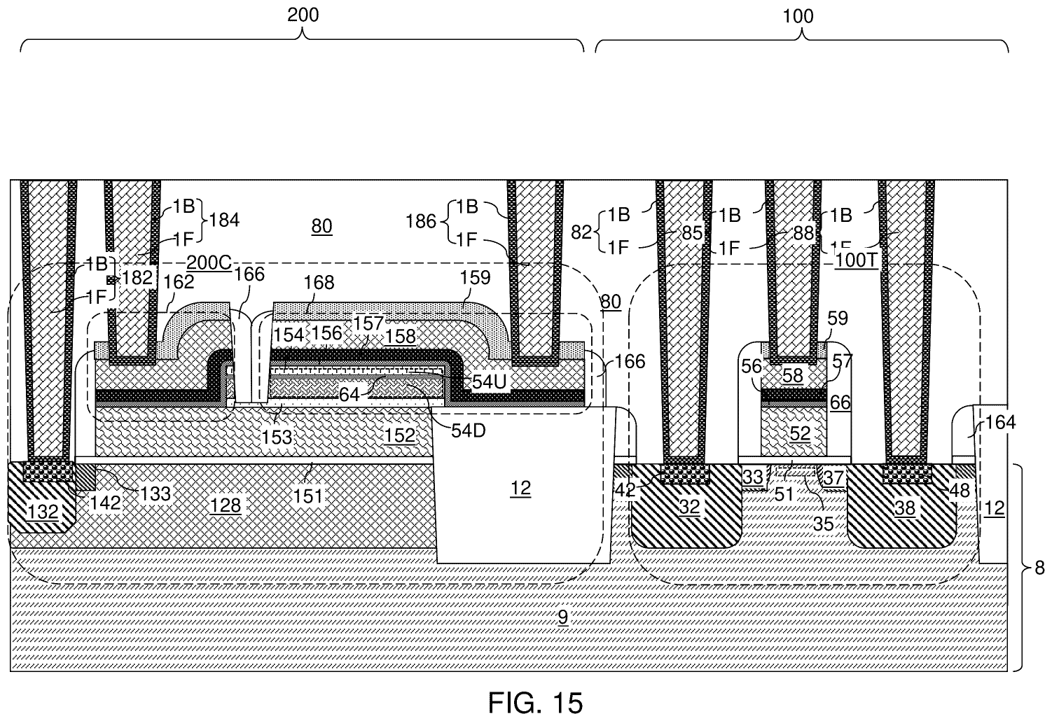

Referring to FIG. 15, various contact via structures (82, 85, 88, 182, 184, 186) can be formed in the contact via cavities (81, 84, 87, 181, 183, 185). For example, a source contact via structure 82 can be formed in the source contact via cavity 81, a gate contact via structure 85 can be formed in the gate contact via cavity 84, a drain contact via structure 88 can be formed in the drain contact via cavity 87, a bottom electrode contact via structure 182 can be formed in the bottom electrode contact via cavity 181, a middle electrode contact via structure 184 can be formed in the middle electrode contact via cavity 183, and a top electrode contact via structure 186 can be formed in the top electrode contact via cavity 185. Alternatively, the peripheral contact via structure 182 may be omitted if the bottom electrode (128, 133, 132, 142) is not externally biased in the completed device. Each of the contact via structures (82, 85, 88, 182, 184, 186) may comprise a respective combination of a metallic barrier liner 1B including a metallic barrier material (such as TiN, TaN, MoN, and/or WN) and a metal fill material portion 1F including a metallic fill material (such as W, Ti, Ta, Mo, Ru, etc.).

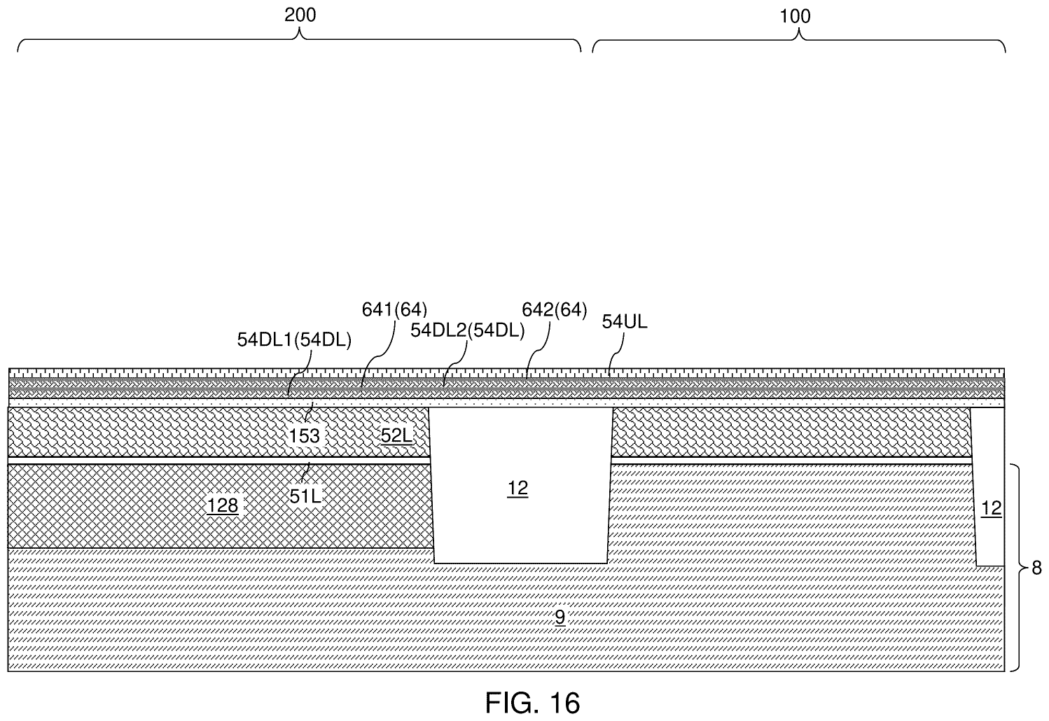

Referring to FIG. 16, an alternative configuration of the exemplary structure according to an embodiment of the present disclosure is illustrated. The alternative configuration of the exemplary structure may be derived from the exemplary structure illustrated in FIG. 3 by forming a top node dielectric material layer 153L by performing processing steps described with reference to FIG. 4, and by forming a vertically alternating sequence of electrically-doped semiconductor layers 54DL and interfacial layers 64, and by subsequently forming an electrically-undoped semiconductor layer 54UL. The top node dielectric material layer 153L in the alternative configuration of the exemplary structure may be the same as the top node dielectric material layer 153L in the exemplary structure of FIG. 4.

The vertically alternating sequence of electrically-doped semiconductor layers 54DL and interfacial layers 64 includes at least two electrically-doped semiconductor layers 54DL that are vertically interlaced with at least two interfacial layers 64 along the vertical direction. In the illustrated example, the at least two electrically-doped semiconductor layers 54DL comprise a first electrically-doped semiconductor layer 54DL1 and a second electrically-doped semiconductor layer 54DL2. The at least two interfacial layers 64 comprises a first interfacial layer 641 and a second interfacial layer 642.

Each of the electrically-doped semiconductor layers 54DL in the alternative configuration of the exemplary structure may be formed by performing processing steps for forming the electrically-doped semiconductor layer 54DL in the exemplary structure illustrated in FIG. 4. The thickness of each of the electrically-doped semiconductor layers 54DL in the alternative configuration of the exemplary structure may be selected such that the sum of all thicknesses of the electrically-doped semiconductor layers 54DL in the alternative configuration of the exemplary structure equals the thickness of the electrically-doped semiconductor layers 54DL in the exemplary structure. For example, the sum of all thicknesses of the electrically-doped semiconductor layers 54DL in the alternative configuration of the exemplary structure may be in a range from 10 nm to 60 nm, such as from 15 nm to 30 nm, although lesser and greater thicknesses may also be employed. For example, if the at least two electrically-doped semiconductor layers 54DL consists of a first electrically-doped semiconductor layer 54DL1 and a second electrically-doped semiconductor layer 54DL2, each of the at least two electrically-doped semiconductor layers 54DL may have a thickness in a range from 5 nm to 30 nm, such as from 7.5 nm to 15 nm, although lesser and greater thicknesses may also be employed.

Each of the at least two interfacial layers 64 may be formed by performing the processing steps for forming the interfacial layer as described with reference to FIG. 5. Each of the at least two interfacial layers 64 may be formed by performing an in-situ oxidation process in a process chamber employed to deposit an underlying electrically-doped semiconductor layer 54DL.

The electrically-undoped semiconductor layer 54UL can be formed by performing the processing steps described with reference to FIG. 6. Generally, the vertically alternating sequence of the electrically-doped semiconductor layers 54DL and the interfacial layers 64 and the electrically-undoped semiconductor layer 54UL may be formed in a same process chamber without unloading the semiconductor substrate 8 from the process chamber prior to deposition of the electrically-undoped semiconductor layer 54UL.

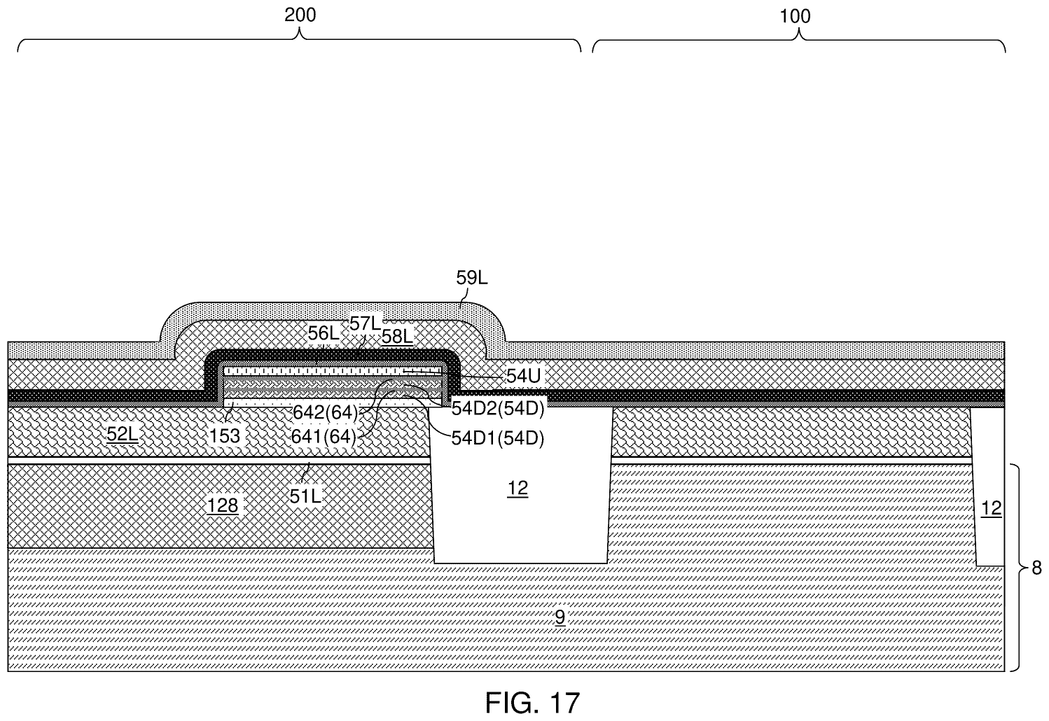

Referring to FIG. 17, the processing steps described with reference to FIGS. 7 and 8 may be patterned to form a patterned stack of an electrically-undoped semiconductor portion 54U, a vertically alternating sequence of interfacial layers 64 and electrically-doped semiconductor portions 54D, and a top node dielectric 153. Sidewalls of the electrically-undoped semiconductor portion 54U, the vertically alternating sequence of the interfacial layers 64 and the electrically-doped semiconductor portions 54D, and the top node dielectric 153 may be vertically coincident, i.e., may be located within a same set of vertical planes. A capping layer stack (56L, 57L, 58L, 59L) including electrode metallic material layers (156L, 157L, 158L) can be formed by performing the processing steps described with reference to FIG. 8.

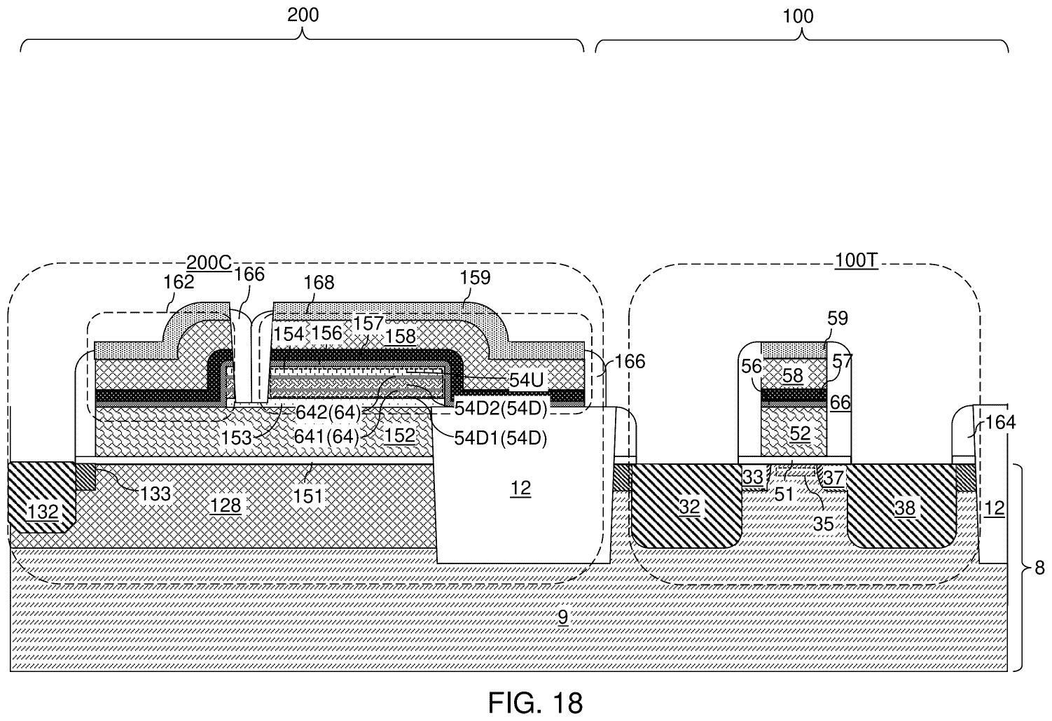

Referring to FIG. 18, the processing steps described with reference to FIGS. 9-12 can be performed to form a capacitor 200C and a field effect transistor 100T. In one embodiment, the top electrode (154, 156, 157, 158) of the capacitor 200C comprises a semiconductor top electrode 154 that includes an electrically-undoped semiconductor portion 54U and a vertically alternating sequence of interfacial layers 64 and electrically-doped semiconductor portions 54D. Thus, the top electrode (154, 156, 157, 158) of the capacitor 200C comprises an electrically-doped semiconductor portion 54D1 and at least one additional electrically-doped semiconductor portion 54D2, and further comprises an interfacial layer 641 and at least one additional interfacial layer 642. The topmost one of the at least one additional interfacial layer 64 contacts a bottom surface of the electrically-doped semiconductor portion 54D.

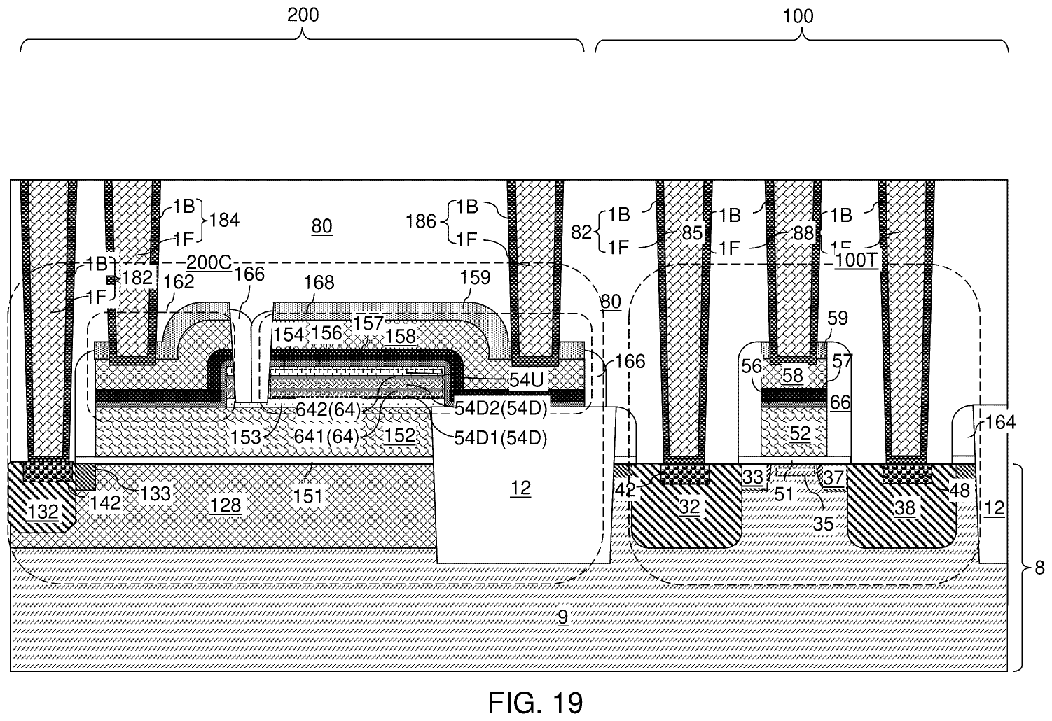

Referring to FIG. 19, the processing steps described with reference to FIGS. 13-15 can be performed to form a contact-level dielectric layer 80 and to form various contact via structures (82, 85, 88, 182, 184, 186).

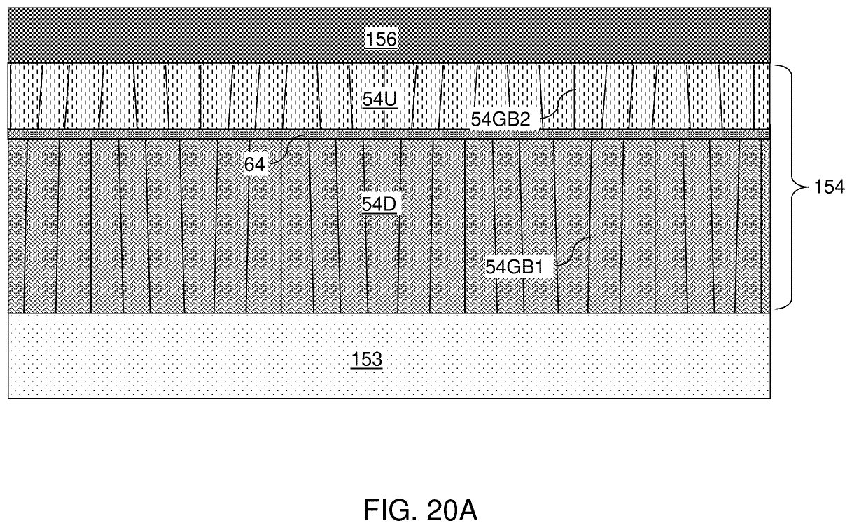

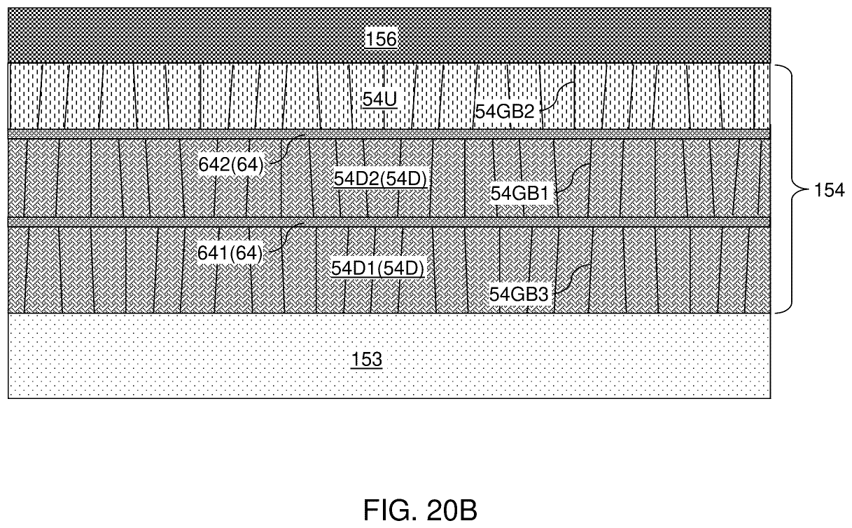

FIGS. 20A and 20B are magnified vertical cross-sectional views of a region of a semiconductor top electrode 154 after an anneal process in various configurations of the exemplary structure according to embodiments of the present disclosure. FIG. 20A illustrates a configuration in which the semiconductor top electrode 154 consists of an electrically-doped semiconductor portion 54D, an interfacial layer 64, and an electrically-undoped semiconductor portion 54U. FIG. 20B illustrates a configuration in which the semiconductor top electrode 154 includes a first electrically-doped semiconductor portion 54D1, a first interfacial layer 641, a second electrically-doped semiconductor portion 54D2, a second interfacial layer 642, and an electrically-undoped semiconductor portion 54U.

The anneal process crystallizes each amorphous semiconductor material within the semiconductor top electrode 154 into a respective polycrystalline semiconductor material. Thus, the anneal process converts a first amorphous semiconductor material into a first crystalline electrically-doped semiconductor material portion (such as the electrically-doped semiconductor portion 54D in FIG. 20A or the first electrically-doped semiconductor portion 54D1 in FIG. 20B having a first columnar crystalline structure containing first grain boundaries 54GB1 that extend predominantly along a vertical direction. Further, the anneal process converts a second amorphous semiconductor material into a crystalline electrically-undoped semiconductor portion 54U having a second columnar crystalline structure containing second grain boundaries 54GB2 that extend predominantly along the vertical direction.

In case two or more electrically-doped semiconductor layer 54DL are employed, the anneal process converts a third amorphous semiconductor material into a second crystalline electrically-doped semiconductor material portion (such as the second electrically-doped semiconductor portion 54D2 in FIG. 20B) having a third columnar crystalline structure containing third grain boundaries 54GB3 that extend predominantly along the vertical direction. Generally, across each interfacial layer 64, bottom edges of overlying grain boundaries are randomly offset relative to top edges of underlying grain boundaries to reduce titanium diffusion from the first electrode metallic layer 155 through the semiconductor top electrode 154 and into the top node dielectric 153 of the capacitor 200C.

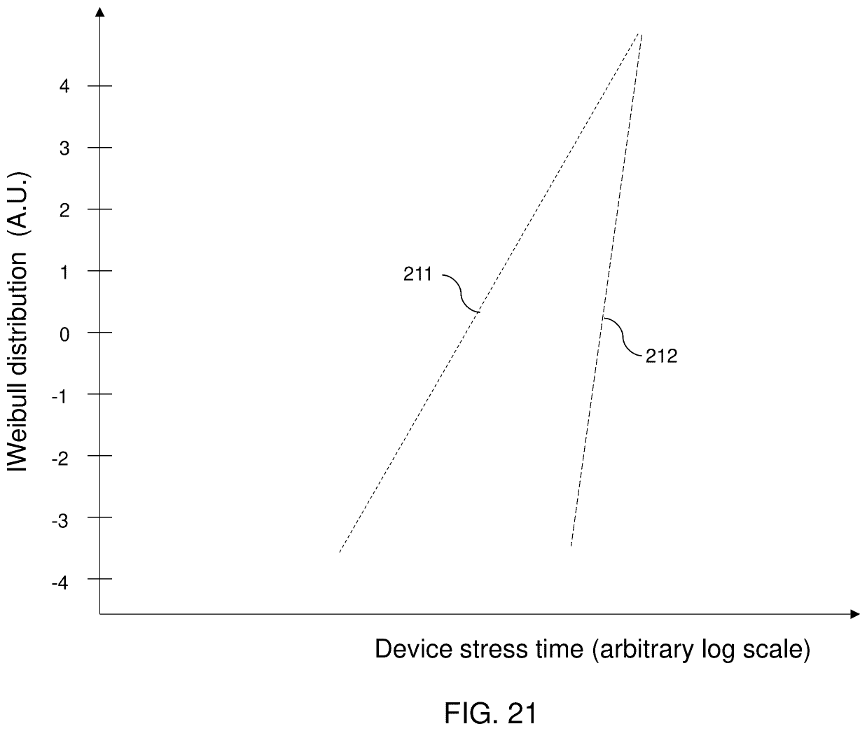

Referring to FIG. 21, a Weibull plot for the cumulative probability F(t) of time-dependent dielectric breakdown (TDDB) failure is illustrated for a comparative exemplary capacitor and for a capacitor 200C according to an embodiment of the present disclosure. The comparative exemplary capacitor is derived from the capacitor 200C of the present disclosure by eliminating each interfacial layer 64, and thus, includes a comparative exemplary semiconductor top electrode in which grains vertically extend continuously from a bottommost surface of the comparative exemplary semiconductor top electrode to the topmost surface of the comparative exemplary semiconductor top electrode. The cumulative probability F(t) of TDDB failure for the comparative exemplary capacitor is illustrated by a first curve 211. The cumulative probability F(t) of TDDB failure for the capacitor 200C according to an embodiment of the present disclosure is illustrated by a second curve 212. Early failures due to TDDB can be reduced for the capacitor 200C according to an embodiment of the present disclosure.

Referring to all drawings and according to various embodiments of the present disclosure, a capacitor 200C includes a substrate (such as a semiconductor substrate 8) a bottom electrode (128, 133, 132, 142) comprising a substrate doped semiconductor portion 128 located within the substrate 8; a bottom node dielectric 151 located on a top surface of the bottom electrode (128, 133, 132, 142); a middle electrode 152 comprising a middle doped semiconductor portion located on the bottom node dielectric 151; a top node dielectric 153 located on a top surface of the middle electrode 152; and a top electrode (154, 156, 157, 158) comprising, from bottom to top, an electrically-doped semiconductor portion 54D, an oxygen containing interfacial layer 64, an electrically-undoped semiconductor portion 54U, and at least one electrode metallic layer (156, 157, 158).

In one embodiment, the interfacial layer 64 has an effective thickness in a range from 0.1 nm to 1.2 nm. In one embodiment, the interfacial layer 64 comprises silicon oxide. In another embodiment, the interfacial layer 64 comprises one or two monolayers of oxygen atoms. In one embodiment, the interfacial layer 64 contacts a top surface of the electrically-doped semiconductor portion 54D and a bottom surface of the electrically-undoped semiconductor portion 54U. In one embodiment, the electrically-undoped semiconductor portion 54U is doped with carbon at an atomic concentration in a range from 1×10¹⁷/cm³ to 5×10²¹/cm³.

In one embodiment, the at least one electrode metallic layer (156, 157, 158) contacts a top surface of the electrically-undoped semiconductor portion 54U. In one embodiment, the at least one electrode metallic layer (156, 157, 158) comprises: a first electrode metallic layer 156 consisting essentially of a transition metal and contacting the electrically-undoped semiconductor portion 54U; and a second electrode metallic layer 157 comprising a conductive metallic nitride material and contacting the first electrode metallic layer 156.

In one embodiment, the first electrode metallic layer 156 comprises: a first horizontally-extending portion that overlies the electrically-undoped semiconductor portion 54U; a vertically-extending portion that contacts sidewalls of the electrically-undoped semiconductor portion 54U, the interfacial layer 64, and the electrically-doped semiconductor portion 54D; and a second horizontally-extending portion that is adjoined to a bottom end of the vertically-extending portion and does not have an areal overlap in a plan view with the electrically-undoped semiconductor portion 54U.

In one embodiment, the first electrode metallic layer 156 consists essentially of titanium; and the second electrode metallic layer 157 consists essentially of titanium nitride. In one embodiment, the at least one electrode metallic layer further comprises a third electrode metallic layer 158 consisting essentially of a transition metal selected from tungsten, molybdenum or tantalum, and contacting the second electrode metallic layer 157.

In one embodiment, a bottom surface of the electrically-doped semiconductor portion 54D contacts a top surface of the top node dielectric 153. In one embodiment, the top electrode (154, 156, 157, 158) comprises: an additional electrically-doped semiconductor portion 54D; and an additional interfacial layer 64 contacting a bottom surface of the electrically-doped semiconductor portion 54D.

In one embodiment, a shallow trench isolation structure 12 is embedded in the substrate and contacts sidewalls of the bottom electrode (128, 133, 132, 142), the bottom node dielectric 151, and the middle electrode 152. In one embodiment, a bottom surface of the first electrode metallic layer 156 contacts a top surface of the shallow trench isolation structure 12.

In one embodiment, the electrically-doped semiconductor portion 54D has a first columnar crystalline structure containing first grain boundaries 54GB1 that extend predominantly along a vertical direction; and the electrically-undoped semiconductor portion 54U has a second columnar crystalline structure containing second grain boundaries 54GB2 that extend predominantly along the vertical direction. In one embodiment, bottom edges of the second grain boundaries 54GB2 are randomly offset relative to top edges of the first grain boundaries 54GB1.

In one embodiment, a semiconductor structure comprises the capacitor 200C and a field effect transistor 100T located on the substrate and laterally offset from the capacitor 200C. A gate dielectric 51 of the field effect transistor and the bottom node dielectric 151 have a same material composition and a same thickness; and a gate electrode (52, 56, 57, 58) of the field effect transistor comprises a doped semiconductor gate electrode 52 having a same material composition and a same thickness as the middle doped semiconductor portion. In one embodiment, the gate electrode (52, 56, 57, 58) of the field effect transistor comprises a metallic gate electrode (56, 57, 58) which has a same set of component layers as the at least one electrode metallic layer (156, 157, 158).

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A capacitor, comprising:
a substrate;
a bottom electrode comprising a substrate doped semiconductor portion located within the substrate;
a bottom node dielectric located on a top surface of the bottom electrode;
a middle electrode comprising a middle doped semiconductor portion located on the bottom node dielectric;
a top node dielectric located on a top surface of the middle electrode; and
a top electrode comprising, from bottom to top, an electrically-doped semiconductor portion, an oxygen containing interfacial layer, an electrically-undoped semiconductor portion, and at least one electrode metallic layer.

2. The capacitor of claim 1, wherein the interfacial layer has an effective thickness in a range from 0.1 nm to 1.2 nm.

3. The capacitor of claim 1, wherein the interfacial layer comprises silicon oxide.

4. The capacitor of claim 1, wherein the interfacial layer comprises one or two monolayers of oxygen atoms.

5. The capacitor of claim 1, wherein the interfacial layer contacts a top surface of the electrically-doped semiconductor portion and a bottom surface of the electrically-undoped semiconductor portion.

6. The capacitor of claim 1, wherein the electrically-undoped semiconductor portion is doped with carbon at an atomic concentration in a range from 1×10¹⁷/cm³ to 5×10²/cm³.

7. The capacitor of claim 1, wherein the at least one electrode metallic layer contacts a top surface of the electrically-undoped semiconductor portion.

8. The capacitor of claim 1, wherein the at least one electrode metallic layer comprises:
a first electrode metallic layer consisting essentially of a transition metal and contacting the electrically-undoped semiconductor portion; and
a second electrode metallic layer comprising a conductive metallic nitride material and contacting the first electrode metallic layer.

9. The capacitor of claim 8, wherein:
the first electrode metallic layer consists essentially of titanium; and
the second electrode metallic layer consists essentially of titanium nitride.

10. The capacitor of claim 9, wherein the at least one electrode metallic layer further comprises a third electrode metallic layer consisting essentially of a transition metal selected from tungsten, molybdenum or tantalum, and contacting the second electrode metallic layer.

11. The capacitor of claim 8, wherein the first electrode metallic layer comprises:
a first horizontally-extending portion that overlies the electrically-undoped semiconductor portion;
a vertically-extending portion that contacts sidewalls of the electrically-undoped semiconductor portion, the interfacial layer, and the electrically-doped semiconductor portion;
a second horizontally-extending portion that is adjoined to a bottom end of the vertically-extending portion and does not have an areal overlap in a plan view with the electrically-undoped semiconductor portion;
a shallow trench isolation structure is embedded in the substrate and contacts sidewalls of the bottom electrode, the bottom node dielectric, and the middle electrode; and
a bottom surface of the first electrode metallic layer contacts a top surface of the shallow trench isolation structure.

12. The capacitor of claim 1, wherein the top electrode further comprises:
an additional electrically-doped semiconductor portion; and
an additional oxygen containing interfacial layer contacting a bottom surface of the electrically-doped semiconductor portion.

13. The capacitor of claim 1, wherein:
the electrically-doped semiconductor portion has a first columnar crystalline structure containing first grain boundaries that extend predominantly along a vertical direction;
the electrically-undoped semiconductor portion has a second columnar crystalline structure containing second grain boundaries that extend predominantly along the vertical direction; and
bottom edges of the second grain boundaries are randomly offset relative to top edges of the first grain boundaries.

14. A semiconductor structure, comprising:
the capacitor of claim 1; and
a field effect transistor located on the substrate and laterally offset from the capacitor, wherein:
a gate dielectric of the field effect transistor and the bottom node dielectric have a same material composition and a same thickness; and
a gate electrode of the field effect transistor comprises a doped semiconductor gate electrode having a same material composition and a same thickness as the middle doped semiconductor portion.

15. The semiconductor structure of claim 14, wherein the gate electrode of the field effect transistor comprises a metallic gate electrode which has a same set of component layers as the at least one electrode metallic layer.

16. A method of forming a semiconductor structure, comprising:
forming a gate dielectric material layer, a gate semiconductor material layer, and a capacitor material layer stack over a substrate, wherein the capacitor material layer stack comprises, from bottom to top, a top node dielectric material layer, a first electrically-doped semiconductor layer, a first oxygen containing interfacial layer, and an electrically-undoped semiconductor layer;
removing a first portion of the capacitor material layer stack from a transistor region while retaining at least a part of a second portion of the capacitor material layer stack in a capacitor region;
forming at least one electrode metallic material layer over the second portion of the capacitor material layer stack in the capacitor region and over the gate semiconductor material layer in the transistor region; and
patterning the at least one electrode metallic material layer, the second portion of the capacitor material layer stack, and the gate semiconductor material layer to form a capacitor in the capacitor region and to form a gate electrode in the transistor region.

17. The method of claim 16, wherein:
the first electrically-doped semiconductor layer is formed by deposition of an electrically doped semiconductor material employing in-situ doping with an electrical dopant in a deposition chamber; and
the first interfacial layer is formed by oxidation of a surface portion of the first electrically-doped semiconductor layer.

18. The method of claim 17, wherein the first interfacial layer is formed by in-situ exposure of the surface portion of the first electrically-doped semiconductor layer to an oxygen-containing ambient in the deposition chamber.

19. The method of claim 18, wherein the electrically-undoped semiconductor layer is formed by deposition of a semiconductor material employing in-situ doping with carbon dopant in the deposition chamber.

20. The method of claim 16, wherein:
the first electrically-doped semiconductor layer comprises a first amorphous semiconductor material layer including atoms of an electrical dopant;
the electrically-undoped semiconductor layer comprises a second amorphous semiconductor material including atoms of an electrically inactive dopant;
the method further comprises performing an anneal process that crystallizes the first amorphous semiconductor material and the second amorphous semiconductor material;
the anneal process converts the first amorphous semiconductor material into a crystalline electrically-doped semiconductor material having a first columnar crystalline structure containing first grain boundaries that extend predominantly along a vertical direction;
the anneal process converts the second amorphous semiconductor material into a crystalline electrically-undoped semiconductor material having a second columnar crystalline structure containing second grain boundaries that extend predominantly along the vertical direction; and
bottom edges of the second grain boundaries are randomly offset relative to top edges of the first grain boundaries.
